(19) United States
(12) Patent Application Publication
(10) Pub. No.: US 2025/0015244 A1
(43) Pub. Date: Jan. 9, 2025

(54) DISPLAY DEVICE AND METHOD OF FABRICATING THE SAME

(71) Applicant: Samsung Display Co., LTD., Yongin-si (KR)

(72) Inventors: Jin Seon KWAK, Yongin-si (KR); Kyung Bae KIM, Yongin-si (KR); Do Yeong PARK, Yongin-si (KR); Yong Hee LEE, Yongin-si (KR)

(21) Appl. No.: 18/763,799

(22) Filed: Jul. 3, 2024

(30) Foreign Application Priority Data
Jul. 7, 2023 (KR) 10-2023-0088594

(51) Int. Cl. H01L 33/62; H01L 25/16

(52) U.S. Cl. CPC H01L 33/62; H01L 25/167; H01L 2933/0066

(57) ABSTRACT

A display device may include: a substrate including a display area and a non-display area, the non-display area including a pad area; a transistor and a conductive pattern on the substrate in the display area; a via layer on the transistor and the conductive pattern to cover the transistor and the conductive pattern; a first alignment electrode and a second alignment electrode on the via layer; a light emitting element between the first and second alignment electrodes; a first electrode and a second electrode that are spaced from each other, and electrically connected to the light emitting element; a plurality of pads on the substrate in the pad area; and a dummy pattern on the substrate in the pad area, and spaced from the plurality of pads. The via layer and the dummy pattern may include a same material.

### CROSS-REFERENCE TO RELATED APPLICATION

The present application claims priority to and the benefit of Korean Patent Application No. 10-2023-0088594, filed on Jul. 7, 2023, in the Korean Intellectual Property Office, the entire disclosure of which is incorporated by reference herein.

### BACKGROUND

### 1. Field

Various embodiments of the present disclosure relate to a display device and a method of fabricating the display device.

### 2. Description of Related Art

Recently, as interest in information display increases, research and development on display devices have been continuously conducted.

### SUMMARY

Various embodiments of the present disclosure are directed to a display device having enhanced reliability, and a method of fabricating the display device.

One or more embodiments of the present disclosure may provide a display device, including: a substrate including a display area and a non-display area, the non-display area including a pad area; a transistor and a conductive pattern on the substrate in the display area; a via layer on the transistor and the conductive pattern to cover the transistor and the conductive pattern; a first alignment electrode and a second alignment electrode on the via layer and spaced from each other; a light emitting element between the first alignment electrode and the second alignment electrode; a first electrode and a second electrode that are spaced from each other, and electrically connected to the light emitting element; a plurality of pads on the substrate in the pad area; and a dummy pattern on the substrate in the pad area, and spaced from the plurality of pads. The via layer and the dummy pattern may include a same material.

The via layer and the dummy pattern may be in a same layer.

The dummy pattern may be adjacent to an edge of each of the plurality of pads.

The dummy pattern may be between two adjacent pads of the plurality of pads.

The display device may further include: a passivation layer located between the substrate and the via layer in the display area, and located between the substrate and the dummy pattern in the pad area; a first insulating layer on the via layer in the display area; and a second insulating layer located on the first insulating layer in the display area, and located on the dummy pattern and the passivation layer in the pad area.

A height of each of the plurality of pads in a thickness direction of the substrate may be different from a height of the dummy pattern.

The height of each of the plurality of pads may be greater than the height of the dummy pattern.

Each of the plurality of pads may include: a first pad electrode on the substrate; and a second pad electrode on the first pad electrode and electrically connected the first pad electrode. The first pad electrode may be in a same layer as the conductive pattern. The second electrode may be in a same layer as at least one of the first electrode or the second electrode.

The conductive pattern may include a first conductive pattern, a second conductive pattern, and a third conductive pattern that are spaced from each other between the substrate and the passivation layer. The first conductive pattern may include an electrode of a storage capacitor electrically connected to the transistor. The second conductive pattern may include a second power line to which a voltage of a second driving power supply is to be applied. The third conductive pattern may include a first power line to which a voltage of a first driving power supply different from the second driving power supply is to be applied.

The passivation layer may include a first opening exposing one area of the first conductive pattern, a second opening exposing a first area of the second conductive pattern, a third opening exposing a second area of the second conductive pattern, a fourth opening exposing one area of the third conductive pattern, and a fifth opening exposing a portion of the first pad electrode. The via layer may include a first contactor exposing the one area of the first conductive pattern, a second contactor exposing the first area of the second conductive pattern, a third contactor exposing the second area of the second conductive pattern, and a fourth contactor exposing the one area of the third conductive pattern. The second insulating layer may include a first contact hole exposing the one area of the first conductive pattern, a second contact hole exposing the second area of the second conductive pattern, and a third contact hole exposing the portion of the first pad electrode.

The first alignment electrode may contact the one area of the third conductive pattern through the fourth contactor and the fourth opening, and may be electrically connected to the third conductive pattern. The second alignment electrode may contact the one area of the second conductive pattern through the second contactor and the second opening, and may be electrically connected to the second conductive pattern.

The first electrode may directly contact the one area of the first conductive pattern through the first contact hole, the first contactor, and the first opening, and may be electrically connected to the first conductive pattern. The second electrode may directly contact the second area of the second conductive pattern through the second contact hole, the third contactor, and the third opening, and may be electrically connected to the second conductive pattern.

The light emitting element may include a first end electrically connected to the first electrode, and a second end electrically connected to the second electrode. The light emitting element may further include a p-type semiconductor layer on the first end, an n-type semiconductor layer on the second end, and an active layer between the p-type semiconductor layer and the n-type semiconductor layer.

The display device may further include: a color conversion layer on the light emitting element and configured to change a wavelength of light emitted from the light emitting element; and a color filter on the color conversion layer.

One or more embodiments of the present disclosure may provide a display device, including: a substrate including a display area and a non-display area, the non-display area including a pad area; a transistor and a conductive pattern on the substrate in the display area; a via layer on the transistor and the conductive pattern to cover the transistor and the conductive pattern; a first alignment electrode and a second alignment electrode on the via layer and spaced from each other; a light emitting element between the first alignment electrode and the second alignment electrode; a first electrode and a second electrode that are spaced from each other, and electrically connected to the light emitting element; a plurality of pads on the substrate in the pad area; and a dummy pattern on the substrate in the pad area, and overlapping each of the plurality of pads. The dummy pattern may include a first layer, a second layer, and a third layer that are successively stacked. At least one of the first layer, the second layer, and the third layer may include a same material as the via layer.

The display device may further include: an interlayer insulating layer located between the substrate and the conductive pattern in the display area, and located between the substrate and the pads in the pad area; a passivation layer on the interlayer insulating layer; a first insulating layer on the via layer in the display area; and a second insulating layer located on the first insulating layer in the display area, and located on the passivation layer in the pad area. The first layer may be in a same layer as the passivation layer, the second layer may be in a same layer as the via layer, and the third layer may be in a same layer as the first insulating layer.

The first layer may include a same material as the passivation layer, the second layer may include a same material as the via layer, and the third layer may include a same material as the first insulating layer.

Each of the plurality of pads may include: a first pad electrode on the interlayer insulating layer; and a second pad electrode on the first pad electrode and the dummy pattern and electrically connected the first pad electrode. The first pad electrode may be in a same layer as the conductive pattern. The second electrode may be in a same layer identical to at least one of the first electrode or the second electrode.

One or more embodiments of the present disclosure may provide a method of fabricating a display device, including: forming a first conductive pattern, a second conductive pattern, a third conductive pattern, and a first pad electrode on a substrate including a display area and a non-display area, the non-display area including a pad area, and forming a passivation layer on the first to the third conductive patterns and the first pad electrode; forming a via pattern including a contactor exposing one area of the passivation layer on the third conductive pattern, a first stepped portion corresponding to the second conductive pattern, and a second stepped portion corresponding to the first pad electrode, by depositing a via material layer on the passivation layer, disposing a mask on the via material layer, and performing a photolithography process; exposing a portion of the third conductive pattern by removing one area of the passivation layer by a dry etching method; forming, on the via pattern in the display area, a first alignment electrode and a second alignment electrode that are spaced from each other; forming, on the via pattern and the first and the second alignment electrodes in the display area, a first insulating layer patterned to expose the first stepped portion; forming a via layer to expose a portion of the passivation layer under the first stepped portion by removing the first stepped portion in the display area by an ashing method, and exposing, by removing the second stepped portion in the pad area by the ashing method, a portion of the passivation layer under the second stepped portion and forming a dummy pattern; aligning light emitting elements between the first alignment electrode and the second alignment electrode in the display area; forming a second insulating layer on the first insulating layer in the display area and the passivation layer in the non-display area; and forming a first electrode and a second electrode electrically connected to the light emitting elements in the display area, and forming a second pad electrode electrically connected to the first pad electrode in the non-display area.

The mask may include a first portion, a second portion, a third portion, and a fourth portion. The first portion may include a transparent portion allowing light to completely pass therethrough. The second portion may include a blocking portion to completely block the light. The third portion may include a semi-transparent portion allowing the light to partially pass therethrough. The fourth portion may include a slit pattern portion having at least one slit pattern.

The first portion may correspond to the contactor of the via pattern, the third portion may correspond to the first stepped portion of the via pattern, the fourth portion may correspond to the second stepped portion of the via pattern, and the second portion may correspond to another area of the via pattern other than the contactor and the first and the second stepped portions.

### BRIEF DESCRIPTION OF THE DRAWINGS

FIG. 1 is a schematic perspective view illustrating a light emitting element in accordance with one or more embodiments.

FIG. 2 is a schematic sectional view illustrating the light emitting element of FIG. 1.

FIG. 3 is a schematic plan view illustrating a display device in accordance with one or more embodiments.

FIG. 4 is a schematic circuit diagram illustrating an electrical connection relationship of components included in a pixel in FIG. 3.

FIG. 5 is a schematic plan view illustrating a display element layer of the pixel in FIG. 3.

FIG. 6 is a schematic sectional view taken along the line II-II′ of FIG. 5.

FIGS. 7 and 8 are schematic sectional views taken along the line III-III′ of FIG. 5.

FIG. 9 is a schematic sectional view taken along the line IV-IV′ and the line V-V′ of FIG. 5.

FIG. 10 illustrates a pixel in accordance with one or more embodiments, and is a schematic sectional view taken along the line III-III′ of FIG. 5.

FIG. 11A is a schematic sectional view taken along the line I-I′ of FIG. 3.

FIG. 11B is a schematic top view of a pad area of FIG. 11A.

FIGS. 12 to 18 are schematic sectional views for sequentially describing a method of fabricating the display device illustrated in FIGS. 9 and 11A.

FIG. 19A is a schematic sectional view taken along the line I-I′ of FIG. 3.

FIG. 19B is a schematic top view of a pad area of FIG. 19A.

FIGS. 20 to 26 are schematic sectional views for sequentially describing a method of fabricating the display device illustrated in FIGS. 9 and 19A.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the technical scope of the present disclosure are encompassed in the present disclosure.

Throughout the present disclosure, like reference numerals refer to like parts throughout the various figures and embodiments of the present disclosure. The sizes of elements in the accompanying drawings may be exaggerated for clarity of illustration. It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be further understood that the terms “comprise,” “include,” “have,” etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them. In addition, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Embodiments and required details of the present disclosure are described with reference to the accompanying drawings in order to describe the present disclosure in detail so that those having ordinary knowledge in the technical field to which the present disclosure pertains can easily practice the present disclosure. Furthermore, a singular form may include a plural form as long as it is not specifically mentioned in a sentence.

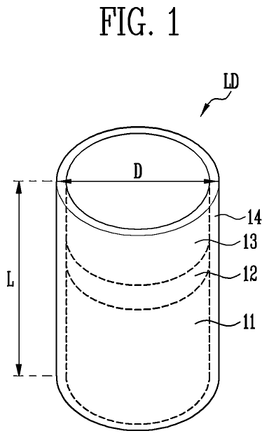

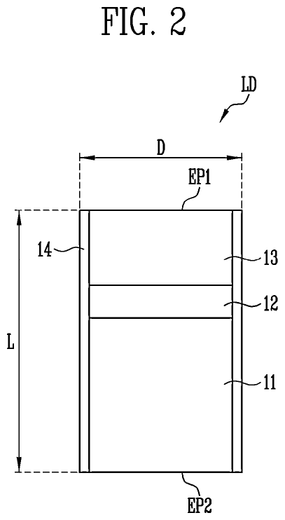

FIG. 1 is a schematic perspective view illustrating a light emitting element LD in accordance with one or more embodiments. FIG. 2 is a schematic sectional view illustrating the light emitting element LD of FIG. 1.

Referring to FIGS. 1 and 2, the light emitting element LD may include a first semiconductor layer 11, a second semiconductor layer 13, and an active layer 12 interposed between the first semiconductor layer 11 and the second semiconductor layer 13. For example, the light emitting element LD may be implemented as an emission stack (or referred to as “light emitting stack pattern”) formed by successively stacking the first semiconductor layer 11, the active layer 12, and the second semiconductor layer 13. The type and/or shape of the light emitting element LD is not limited to that of the embodiment illustrated in FIG. 1.

The light emitting element LD may be formed in a shape extending in one direction. If the direction in which the light emitting element LD extends is defined as a longitudinal direction, the light emitting element LD may have a first end EP1 and a second end EP2 that are opposite to each other along the longitudinal direction. For example, the second semiconductor layer 13 may be disposed on the first end EP1 of the light emitting element LD, and the first semiconductor layer 11 may be disposed on the second end EP2 of the light emitting element LD. However, the present disclosure is not limited to the foregoing example.

The light emitting element LD may be provided in various shapes. For example, as illustrated in FIG. 1, the light emitting element LD may have a rod-like shape, a bar-like shape, or a pillar-like shape which is long in the longitudinal direction (e.g., has an aspect ratio greater than 1). The light emitting element LD may include a light emitting diode (LED) fabricated to have a subminiature size, e.g., with a diameter D and/or a length L corresponding to a range from the nano-scale (or the nanometer scale) to the micro-scale (or the micrometer scale).

In the case where the light emitting element LD is long with respect to the longitudinal direction, the diameter D of the light emitting element LD may approximately range from 0.5 μm to 6 μm, and the length L thereof may approximately range from 1 μm to 10 μm. However, the diameter D and the length L of the light emitting element LD are not limited thereto. The size of the light emitting element LD may be changed to meet requirements (or design conditions) of a lighting device or a self-emissive display device to which the light emitting element LD is applied.

The first semiconductor layer 11 may include, for example, at least one n-type semiconductor layer. For instance, the first semiconductor layer 11 may include an n-type semiconductor layer which includes at least one semiconductor material of InAlGaN, GaN, AlGaN, InGaN, AlN, and/or InN and is doped with a first conductive dopant (or an n-type dopant) such as, for example, Si, Ge, and/or Sn. However, the constituent material of the first semiconductor layer 11 is not limited to thereto, and various other materials may be used to form the first conductive semiconductor layer 11.

The active layer 12 (or an emission layer) may be disposed on the first semiconductor layer 11 and have a single or multiple quantum well structure. For example, in the case in which the active layer 12 has a multiple quantum well structure, the active layer 12 may be formed by periodically repeatedly stacking a barrier layer, a stain reinforcing layer, and a well layer as one unit. However, the structure of the active layer 12 is not limited to that of the foregoing embodiment.

The active layer 12 may emit light having a wavelength ranging from 400 nm to 900 nm, and have a double hetero structure. In one or more embodiments, a clad layer doped with a conductive dopant may be formed over or under the active layer 12 along the longitudinal direction of the light emitting element LD. For example, the clad layer may be formed of an AlGaN layer or an InAlGaN layer. In one or more embodiments, material such as AlGaN or InAlGaN may be used to form the active layer 12, and various other materials may be used to form the active layer 12.

If an electric field having a certain voltage or more is applied to the opposite ends of the light emitting element LD, the light emitting element LD may emit light by coupling of electron-hole pairs in the active layer 12. Because light emission of the light emitting element LD can be controlled based on the foregoing principle, the light emitting element LD may be used as a light source (a light emitting source) of various light emitting devices as well as a pixel of a display device.

The second semiconductor layer 13 may be disposed on the active layer 12 and include a semiconductor layer of a type different from that of the first semiconductor layer 11. For example, the second semiconductor layer 13 may include at least one p-type semiconductor layer. For instance, the second semiconductor layer 13 may include a p-type semiconductor layer which includes any semiconductor material of InAlGaN, GaN, AlGaN, InGaN, AlN, and/or InN, and is doped with a second conductive dopant (or a p-type dopant) such as Mg, Zn, Ca, Sr, and/or Ba. However, the material for forming the second semiconductor layer 13 is not limited thereto, and various other materials may be used to form the second semiconductor layer 13.

The first semiconductor layer 11 and the second semiconductor layer 13 may have different thicknesses in the longitudinal direction of the light emitting element LD. For example, the first semiconductor layer 11 may have a thickness greater than that of the second semiconductor layer 13 in the longitudinal direction of the light emitting element LD, but the present disclosure is not limited thereto.

Although FIGS. 1 and 2 illustrate that each of the first semiconductor layer 11 and the second semiconductor layer 13 is formed of a single layer, the present disclosure is not limited thereto. In one or more embodiments, depending on the material of the active layer 12, each of the first semiconductor layer 11 and the second semiconductor layer 13 may further include at least one or more layers, for example, a clad layer and/or a tensile strain barrier reducing (TSBR) layer. In one or more embodiments, the light emitting element LD may further include a contact electrode (hereinafter referred to as “first contact electrode”) disposed over the second semiconductor layer 13, as well as including the first semiconductor layer 11, the active layer 12, and the second semiconductor layer 13. Furthermore, in one or more embodiments, the light emitting element LD may further include an additional contact electrode (hereinafter referred to as “second contact electrode”) disposed on one end of the first semiconductor layer 11.

Each of the first and second contact electrodes may be an ohmic contact electrode, but the present disclosure is not limited thereto. In one or more embodiments, each of the first and second contact electrodes may be a Schottky contact electrode.

Materials included in the first and second contact electrodes may be identical to or different from each other. The first and second contact electrodes may be substantially transparent or translucent.

In one or more embodiments, the light emitting element LD may further include an insulating layer 14. However, depending on the embodiment, the insulating layer 14 may be omitted, or may be provided to cover only some of the first semiconductor layer 11, the active layer 12, and the second semiconductor layer 13.

The insulating layer 14 may prevent the active layer 12 from short-circuiting due to contacting conductive material except the first and second semiconductor layers 11 and 13. Furthermore, the insulating layer 14 may reduce or minimize a surface defect of the light emitting element LD, thus enhancing the lifetime and emission efficiency of the light emitting element LD. In the case in which a plurality of light emitting elements LD are disposed in close contact with each other, the insulating layer 14 may prevent an undesired short-circuit from occurring between the light emitting elements LD. The presence or non-presence of the insulating layer 14 is not limited, so long as the active layer 12 can be prevented from short-circuiting with external conductive material.

The insulating layer 14 may be provided to be around (e.g., to surround or to enclose) an overall outer surface (e.g., an outer peripheral or circumferential surface) of the emission stack including the first semiconductor layer 11, the active layer 12, and the second semiconductor layer 13, but is not limited thereto.

The insulating layer 14 may include transparent insulating material. Various materials having insulation properties may be used as the material of the insulating layer 14. The insulating layer 14 may have a single-layer structure or a multilayer structure including a double-layer structure.

In one or more embodiments, the light emitting element LD may be implemented as a light emitting pattern having a core-shell structure.

The light emitting element LD may be employed as a light emitting source (or a light source) for various display devices. The light emitting element LD may be fabricated through a surface treatment process.

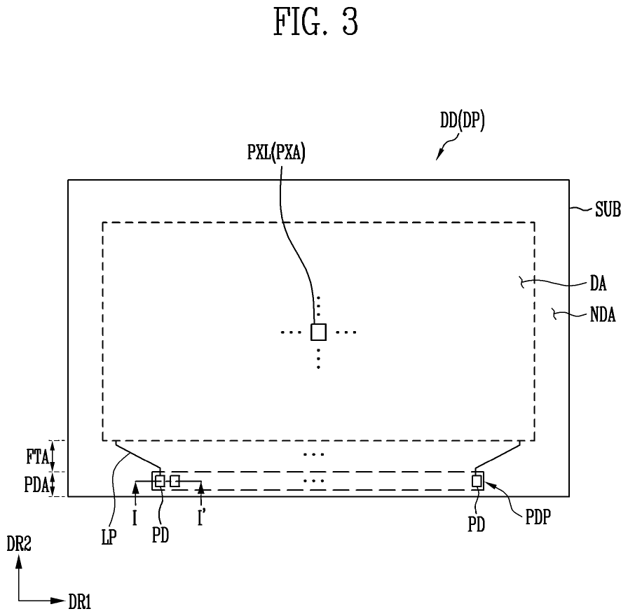

FIG. 3 is a schematic plan view illustrating the display device DD in accordance with one or more embodiments.

In FIG. 3, for the sake of explanation, there is schematically illustrated the structure of the display device DD, for example, a display panel DP provided in the display device DD, centered on a display area DA in which an image is displayed.

Referring to FIGS. 1 to 3, the display device DD (or the display panel DP) may include a substrate SUB, pixels PXL provided on the substrate SUB and each including at least one light emitting element LD, a driver provided on the substrate SUB and configured to drive the pixels PXL, and a line component provided to electrically connect the pixels PXL with the driver.

The substrate SUB may include transparent insulating material to allow light transmission. The substrate SUB may be a rigid substrate or a flexible substrate.

For example, the rigid substrate may be one of a glass substrate, a quartz substrate, a glass ceramic substrate, and/or a crystalline glass substrate, but is not limited thereto.

The flexible substrate may be either a film substrate or a plastic substrate which includes polymer organic material. For example, the flexible substrate SUB may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate.

One area of the substrate SUB may be provided as the display area DA in which the pixels PXL are disposed, and the other area of the substrate SUB may be provided as the non-display area NDA. For example, the substrate SUB may include the display area DA where there are defined pixel areas PXA on which the respective pixels PXL are disposed, and the non-display area NDA disposed around an edge or a perimeter of the display area DA (or adjacent to the display area DA).

The non-display area NDA may be provided on at least one side of the display area DA. The non-display area NDA may enclose the perimeter (or edges) of the display area DA. In the non-display area NDA, there are disposed the line component and the driver. For example, the non-display area NDA may be an area in which fan-out lines LP, pads PD, and/or an internal circuit component that are electrically connected with the pixels PXL to drive the pixels PXL are disposed.

The non-display area NDA may include a fan-out area FTA and a pad area PDA.

The pad area PDA may be one area of the non-display area NDA in which the pad component PDP is positioned, and may be disposed most adjacent to a perimeter (or an edge) of the non-display area NDA. The fan-out area FTA may be another area of the non-display area NDA in which the fan-out lines LP are positioned, and may be disposed adjacent to the display area DA in the non-display area NDA. For example, the fan-out area FTA may be one area of the non-display area NDA that is disposed between the pad area PDA and the display area DA. In one or more embodiments, the non-display area NDA may include an antistatic circuit area in which there is disposed an antistatic circuit which is electrically connected to signal lines disposed in the display area DA and is configured to prevent static electricity from occurring.

The pad component PDP may be disposed in the pad area PDA. The fan-out lines LP may be disposed in the fan-out area FTA.

The fan-out lines LP may be electrically connected to the pixels PXL so that certain signals applied from the driver may be transmitted to the pixels PXL. The fan-out lines LP may be connection components positioned in the fan-out area FTA to electrically connect the driver to the pixels PXL.

The pad component PDP may include a plurality of pads PD. The pads PD may supply driving power voltages and signals for driving the pixels PXL disposed in the display area DA and/or the internal circuit component. In one or more embodiments, in the case in which the driver is mounted in the non-display area NDA of the substrate SUB, the pad component PDP may overlap an output pad of the driver and receive a signal outputted from the driver. In one or more embodiments, the pads PD may be electrically connected to an external circuit substrate by a conductive adhesive component.

Each of the pixels PXL may be disposed in the pixel area PXA. The pixels PXL may be arranged in the display area DA in a stripe arrangement manner or the like, but the present disclosure is not limited thereto.

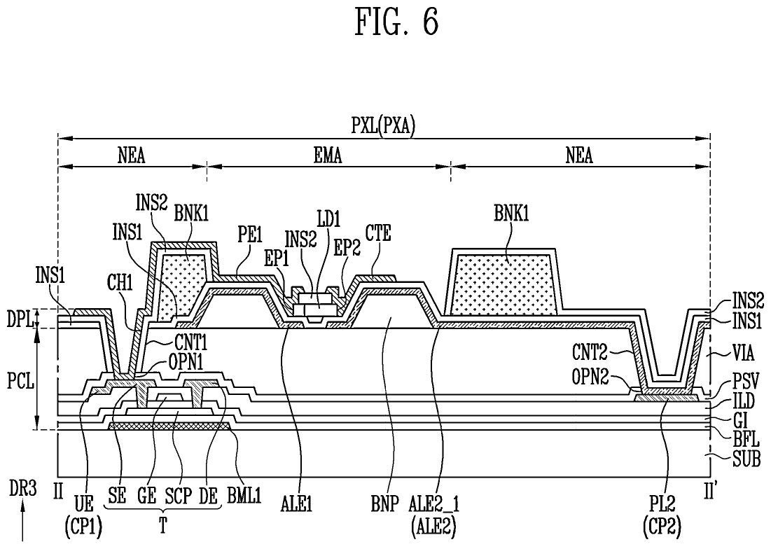

Each pixel PXL may include a pixel circuit layer (refer to “PCL” of FIG. 6) positioned on the substrate SUB, and a display element layer (refer to “DPL” of FIG. 6) positioned on the pixel circuit layer PCL.

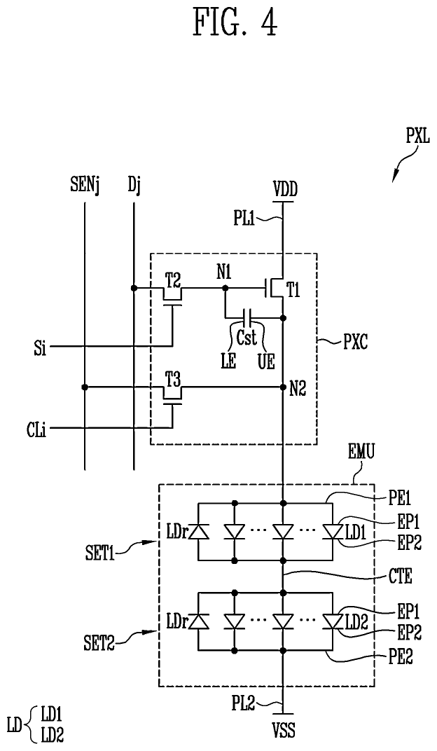

A pixel circuit (refer to “PXC” of FIG. 4) which is provided on the substrate SUB and includes a plurality of transistors and signal lines connected to the transistors may be disposed in the pixel circuit layer PCL. Each transistor has a structure in which, for example, a semiconductor layer, a gate electrode, a first terminal, and a second terminal are successively stacked with insulating layers interposed therebetween. The semiconductor layer may include amorphous silicon, poly silicon, low temperature poly silicon, and/or an organic semiconductor, and/or an oxide semiconductor. Although each of the gate electrode, the first terminal (or a drain electrode), and the second terminal (or a source electrode) may include one of aluminum (Al), copper (Cu), titanium (Ti), and/or molybdenum (Mo), the present disclosure is not limited thereto. In addition, the pixel circuit layer PCL may include at least one or more insulating layers.

In the display element layer DPL, there may be disposed an emission component (refer to “EMU” of FIG. 4) including a light emitting element LD electrically connected to the transistors to emit light.

FIG. 4 is a schematic circuit diagram illustrating an electrical connection relationship of components included in the pixel PXL of FIG. 3.

For example, FIG. 4 illustrates the electrical connection relationship of components included in the pixel PXL that may be employed in an active matrix type display device in accordance with one or more embodiments. Here, the connection relationship of the components of each pixel PXL is not limited thereto.

Referring to FIGS. 1 to 4, the pixel PXL may include an emission component EMU configured to generate light having a luminance corresponding to a data signal. Furthermore, the pixel PXL may include a pixel circuit PXC configured to drive the emission component EMU.

For example, the emission component EMU may include a first electrode PE1 (or a first pixel electrode) electrically connected to a first driving power supply VDD by the pixel circuit PXC and a first power line PL1, a second electrode PE2 (or a second pixel electrode) electrically connected to a second driving power supply VSS by a second power line PL2, and a plurality of light emitting elements LD electrically connected between the first electrode PE1 and the second electrode PE2. The first driving power supply VDD and the second driving power supply VSS may have different potentials to allow the light emitting elements LD to emit light. For example, the first driving power supply VDD may be set to a high-potential power supply, and the second driving power supply VSS may be set to a low-potential power supply.

In one or more embodiments, the emission component EMU may include at least one series stage. Each series set may include a pair of electrodes (e.g., two electrodes), and at least one light emitting element LD electrically connected in a forward direction between the pair of electrodes. In one or more embodiments, the number of series sets that form the emission component EMU and the number of light emitting elements LD that form each series set are not limited. For example, the numbers of light emitting elements LD that form the respective series sets may be identical to or different from each other. The number of light emitting elements LD of each series set is not particularly limited.

For example, the emission component EMU may include a first series set SET1 including at least one first light emitting element LD1, and a second series set SET2 including at least one second light emitting element LD2.

The first series set SET1 may include a first electrode PE1, an intermediate electrode CTE (or a bridge electrode), and at least one first light emitting element LD1 electrically connected between the first electrode PE1 and the intermediate electrode CTE. Each first light emitting element LD1 may be connected in the forward direction between the first electrode PE1 and the first intermediate electrode CTE. For example, the first end EP1 of the first light emitting element LD1 may be electrically connected to the first electrode PE1. The second end EP2 of the first light emitting element LD1 may be electrically connected to the intermediate electrode CTE.

The second series set SET2 may include the intermediate electrode CTE, a second electrode PE2, and at least one second light emitting element LD2 electrically connected between the intermediate electrode CTE and the second electrode PE2. Each second light emitting element LD2 may be connected in the forward direction between the intermediate electrode CTE and the second electrode PE2. For example, the first end EP1 of the second light emitting element LD2 may be electrically connected to the intermediate electrode CTE. The second end EP2 of the second light emitting element LD2 may be electrically connected to the second electrode PE2.

The 1st electrode of the emission component EMU, e.g., the first electrode PE1, may be an anode of the emission component EMU. The last electrode of the emission component EMU, e.g., the second electrode PE2, may be a cathode of the emission component EMU.

In case that the light emitting elements LD are connected to have a series/parallel structure, power efficiency may be enhanced, compared to the case where the same number of light emitting elements LD are connected only in parallel to each other. Furthermore, in the pixel PXL in which the light emitting elements LD are connected to have a series/parallel structure, sufficient luminance can be expressed by the light emitting elements LD of some series stages, so that the probability of occurrence of a black spot defect in the pixel PXL can be reduced. However, the present disclosure is not limited thereto. The emission component EMU may be formed by connecting the light emitting elements LD only in series. Alternatively, the emission component EMU may be formed by connecting the light emitting elements LD only in parallel.

Each of the light emitting elements LD may include a first end EP1 (e.g., a p-type end) electrically connected to the first driving power supply VDD via at least one electrode (e.g., the first electrode PE1), the pixel circuit PXC, the first power line PL1, and/or the like, and a second end EP2 (e.g., an n-type end) electrically connected to the second driving power supply VSS via at least one electrode (e.g., the second electrode PE2), the second power line PL2, and/or the like. For example, the light emitting elements LD may be electrically connected in the forward direction between the first driving power supply VDD and the second driving power supply VSS. The light emitting elements LD that are electrically connected in the forward direction may form valid light sources of the emission component EMU.

In one or more embodiments, the emission component EMU may further include at least one reverse light emitting element LDr, as well as including the light emitting elements LD that form the respective valid light sources.

The light emitting elements LD of the emission component EMU may emit light having a luminance corresponding to driving current supplied thereto through the pixel circuit PXC. For example, during each frame period, the pixel circuit PXC may supply driving current corresponding to a grayscale value of a corresponding frame data to the light emitting component EMU. The driving current supplied to the emission component EMU may be divided into parts which flow into the respective light emitting elements LD. Hence, each of the light emitting elements LD may emit light having a luminance corresponding to current applied thereto, so that the light emitter EMU may emit light having a luminance corresponding to the driving current.

The pixel circuit PXC may be connected to a scan line Si and a data line Dj of the corresponding pixel PXL. For example, if the pixel PXL is disposed on an i-th row and a j-th column of the display area DA, the pixel circuit PXC of the pixel PXL may be connected to an i-th scan line Si and a j-th data line Dj of the display area DA. Furthermore, the pixel circuit PXC may be connected to an i-th control line CLi and a j-th sensing line SENj of the display area DA.

The pixel circuit PXC may include first to third transistors T1, T2, and T3, and a storage capacitor Cst.

The first transistor T1 may be a driving transistor configured to control driving current to be applied to the emission component EMU, and may be electrically connected between the first driving power supply VDD and the emission component EMU. In detail, a first terminal of the first transistor T1 may be electrically connected to the first driving power supply VDD by the first power line PL1. A second terminal of the first transistor T1 may be electrically connected to a second node N2. A gate electrode of the first transistor T1 may be electrically connected to a first node N1. The first terminal of the first transistor T1 may be a drain electrode, and the second terminal of the first transistor T1 may be a source electrode.

The second transistor T2 may be a switching transistor which selects a pixel PXL in response to a scan signal and activates the pixel PXL, and may be electrically connected between the j-th data line Dj and the first node N1. A first terminal of the second transistor T2 may be electrically connected to the j-th data line Dj. A second terminal of the second transistor T2 may be electrically connected to the first node N1 (or the gate electrode of the first transistor T1). A gate electrode of the second transistor T2 may be electrically connected to the i-th scan line Si. The first terminal and the second terminal of the second transistor T2 are different terminals, and, for example, if the first terminal is a drain electrode, the second terminal may be a source electrode.

When a scan signal of a gate-on voltage (e.g., a high level voltage) is supplied from the i-th scan line Si, the second transistor T2 may be turned on to electrically connect the j-th data line Dj to the first node N1. The first node N1 may be a point at which the second terminal of the second transistor T2 and the gate electrode of the first transistor T1 are electrically connected to each other. The second transistor T2 may transmit a data signal to the gate electrode of the first transistor T1.

The third transistor T3 may acquire a sensing signal through the j-th sensing line SENj by electrically connecting the first transistor T1 to the j-th sensing line SENj, and detect, using the sensing signal, characteristics of the pixel PXL such as a threshold voltage of the first transistor T1. Information about the characteristics of the pixel PXL may be used to convert image data such that a deviation in characteristic between pixels PXL can be compensated for. A second terminal of the third transistor T3 may be electrically connected to the second terminal of the first transistor T1 and the second node N2. A first terminal of the third transistor T3 may be electrically connected to the j-th sensing line SENj. A gate electrode of the third transistor T3 may be electrically connected to the i-th control line CLi. The first terminal of the third transistor T3 may be a drain electrode, and the second terminal of the third transistor T3 may be a source electrode.

Furthermore, the first terminal of the third transistor T3 may be electrically connected to an initialization power supply. The third transistor T3 may be an initialization transistor configured to initialize the second node N2, and may be turned on when a sensing control signal is supplied thereto from the i-th control line CLi, so that the voltage of the initialization power supply can be transmitted to the second node N2. Hence, an upper electrode UE (or a second storage electrode) of the storage capacitor Cst that is electrically connected to the second node N2 may be initialized.

The storage capacitor Cst may include a lower electrode LE (or a first storage electrode) and an upper electrode UE (or a second storage electrode). The lower electrode LE may be electrically connected to the first node N1. The upper electrode UE may be electrically connected to the second node N2. The storage capacitor Cst may be charged with a gate voltage corresponding to a data signal to be supplied to the first node N1 during one frame period. Hence, the storage capacitor Cst may store a voltage corresponding to a difference between a voltage of the gate electrode of the first transistor T1 and a voltage of the second node N2.

Although FIG. 4 illustrates one or more embodiments where all of the first to third transistors T1, T2, and T3 are N-type transistors, the present disclosure is not limited thereto. For example, at least one of the first to third transistors T1, T2, and T3 may be changed to a P-type transistor. In one or more embodiments, the emission component EMU may be connected between the first driving power supply VDD and the pixel circuit PXC.

The structure of the pixel circuit PXC may be changed in various ways.

In the following embodiments, for the sake of explanation, a transverse direction (or an X-axis direction) in a plan view will be indicated by a first direction DR1, a longitudinal direction (or a Y-axis direction) in a plan view will be indicated by a second direction DR2, and a vertical direction in a sectional view will be indicated by a third direction DR3.

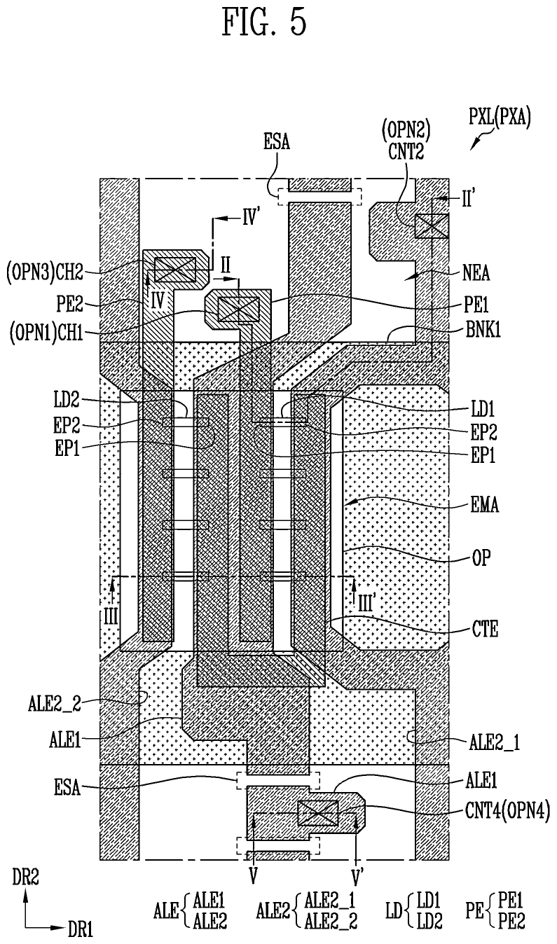

FIG. 5 is a schematic plan view illustrating the display element layer DPL of the pixel PXL of FIG. 3.

In FIG. 5, for convenience of explanation, illustration of the pixel circuit including the transistors electrically connected to the light emitting elements LD is omitted.

In FIG. 5, not only the components included in the pixel PXL but also an area in which the components are positioned may be embraced in the definition of the term “pixel PXL”.

Referring to FIGS. 1 to 5, the pixel PXL may be positioned in a pixel area PXA provided on the substrate SUB. The pixel area PXA may include an emission area EMA and a non-emission area NEA.

The pixel PXL may include a first bank BNK1 positioned in the non-emission area NEA, and light emitting elements LD located in the emission area EMA.

The first bank BNK1 may be a structure for defining the respective emission areas EMA of the pixel PXL and pixels PXL adjacent thereto and, for example, may be a pixel defining layer. The first bank BNK1 may be a pixel defining layer or a dam structure for defining each emission area EMA to which the light emitting elements LD are to be supplied, during a process of supplying (or inputting) the light emitting elements LD. The emission area EMA of the pixel PXL may be defined by the first bank BNK1, thus enabling a mixed solution (e.g., ink) including a target amount and/or type of light emitting elements LD to be supplied (or inputted) to the emission area EMA.

The first bank BNK1 may include at least one light blocking material and/or reflective material (or scattering material), thus preventing a light leakage defect in which light leaks between the pixel PXL and the pixels PXL adjacent thereto. In one or more embodiments, the first bank BNK1 may include transparent material (or substance). The transparent material may include, for example, polyamides resin, polyimides resin, and/or the like, but the present disclosure is not limited thereto. In one or more embodiments, in order to enhance the efficiency of light emitted from the pixel PXL, a separate reflective layer may be provided and/or formed on the first bank BNK1.

The first bank BNK1 may include, in the pixel area PXA, at least one opening OP which exposes components disposed underneath. The emission area EMA of the pixel PXL and the opening OP of the first bank BNK1 may correspond to each other.

An electrode separation area ESA may be disposed in the non-emission area NEA of each pixel PXL. The electrode separation area ESA may be an area in which a first alignment electrode ALE1 in each pixel PXL is separated from first alignment electrodes ALE1 provided in the pixels PXL arranged in the same pixel column.

The pixel PXL may include electrodes PE (or pixel electrodes) provided in the emission area EMA, light emitting elements LD electrically connected to the electrodes PE, and alignment electrodes ALE provided at positions corresponding to the electrodes PE. For example, a first electrode PE1 (or a first pixel electrode), a second electrode PE2 (or a second pixel electrode), the light emitting elements LD, and first and second alignment electrodes ALE1 and ALE2 may be disposed in the emission area EMA. Furthermore, an intermediate electrode CTE (or a bridge electrode) may be disposed in the emission area EMA. The number, shape, size, arrangement structure, etc., of the electrodes PE and/or the alignment electrodes ALE may be changed in various ways depending on the structure of the pixel PXL (or the emission component EMU).

Based on one surface of the substrate SUB on which the pixel PXL is provided, the alignment electrodes ALE, the light emitting elements LD, and the electrodes PE may be provided in the order listed, but the present disclosure is not limited thereto. Description of a stacked structure of the pixel PXL will be described below with reference to FIGS. 6 to 9.

The alignment electrodes ALE may be disposed in at least the emission area EMA, and may be spaced from each other in the first direction DR1 in the emission area EMA, and each may extend in the second direction DR2. The alignment electrodes ALE may include a 2-2-th alignment electrode ALE2_2, a first alignment electrode ALE1, and a 2-1-th alignment electrode ALE2_1 that are spaced from each other in the first direction DR1.

At least one of the 2-2-th alignment electrode ALE2_2, the first alignment electrode ALE1, and the 2-1-th alignment electrode ALE2_1 may be separated from other electrodes (e.g., an alignment electrode ALE provided in each of the pixels PXL arranged on the same pixel column as each pixel PXL) after the light emitting elements LD have been supplied to and aligned in the emission area EMA during a process of fabricating the display device DD. For example, the first alignment element ALE1 may be separated from first alignment electrodes ALE1 provided in adjacent pixels PXL arranged on the same pixel column as the corresponding pixel PXL after the light emitting elements LD have been supplied to and aligned in the emission area EMA during the process of fabricating the display device DD.

The first alignment electrodes ALE1 provided in the display area DA may be formed to be connected to each other during the process of fabricating the display device DD. For example, the first alignment electrodes ALE1 may be connected to each other without being partially removed, thus forming a first alignment line. The first alignment line may be electrically connected to the first power line (refer to “PL1” of FIG. 4) of the pixel circuit (refer to “PXC” of FIG. 4) through a fourth contactor CNT4 and a fourth opening OPN4. During a process of aligning the light emitting elements LD, a first alignment signal may be supplied to the first alignment line through the first power line PL1. After the process of aligning the light emitting elements LD has been completed, a portion of the first alignment line around the fourth contactor CNT4 and the fourth opening OPN4 positioned in the non-emission area NEA may be removed (or the first alignment line may be cut off), whereby the electrical connection between the first alignment electrodes ALE1 and the first power line PL1 may be interrupted. Furthermore, the first alignment line may be cut off in the electrode separation area ESA between adjacent pixel columns so that the first alignment electrodes ALE1 of adjacent pixels PXL can be separated from each other. Therefore, the first alignment electrodes ALE1 of the pixels PXL disposed on the same pixel column may be electrically separated from each other, whereby the pixels PXL may be individually driven.

In one or more embodiments, the fourth contactor CNT4 and the fourth opening OPN4 may be formed by removing portions of two or more insulating layers disposed between the first alignment electrode ALE1 and the first power line PL1.

The 2-2-th alignment electrode ALE2_2 may be disposed adjacent to one side (e.g., a left side) of the first alignment electrode ALE1 in a plan view, and the 2-1-th alignment electrode ALE2_1 may be disposed adjacent to another side (e.g., a right side) of the first alignment electrode ALE1 in a plan view. The 2-1-th alignment electrode ALE2_1 and the 2-2-th alignment electrode ALE2_2 may be integrally formed and electrically connected to each other, thus forming the second alignment electrode ALE2.

The 2-1-th alignment electrode ALE2_1 may be electrically connected to the second power line (refer to “PL2” of FIG. 4) through a second contactor CNT2 and a second opening OPN2. The second contactor CNT2 and the second opening OPN2 may be formed by removing portions of two or more insulating layers disposed between the 2-1-th alignment electrode ALE2_1 and the second power line PL2.

Each of the 2-2-th alignment electrode ALE2_2, the first alignment electrode ALE1, and the 2-1-th alignment electrode ALE2_1 may be used as an alignment line provided for alignment of the light emitting elements LD and configured to receive a signal (e.g., an alignment signal) before the light emitting elements LD are aligned in the emission area EMA of the first sub-pixel SPXL1.

Each of the 2-2-th alignment electrode ALE2_2, the first alignment electrode ALE1, and the 2-1-th alignment electrode ALE2_1 may be provided in the form of a bar having a constant width in at least the emission area EMA, but the present disclosure is not limited thereto. Each of the 2-2-th alignment electrode ALE2_2, the first alignment electrode ALE1, and the 2-1-th alignment electrode ALE2_1 may or may not have a bent portion in the non-emission area NEA, and the shape, size, and/or other characteristics of the electrodes in the other areas except the emission area EMA may be changed in various ways without being particularly limited.

At least two or more light emitting elements LD may be aligned in the emission area EMA (or the pixel area PXA). The light emitting elements LD may be disposed between the first alignment electrode ALE1 and the 2-1-th alignment electrode ALE2_1 and between the first alignment electrode ALE1 and the 2-2-th alignment electrode ALE2_2. In a plan view, each of the light emitting elements LD may include a first end EP1 and a second end EP2 which are positioned on respective opposite ends of the light emitting element LD in the longitudinal direction thereof, e.g., in the first direction DR1. The second semiconductor layer (refer to “13” of FIG. 1) including a p-type semiconductor layer may be disposed on the first end EP1 (or the p-type end), and the first semiconductor layer (refer to “11” of FIG. 1) including an n-type semiconductor layer may be disposed on the second end EP2 (or the n-type end). The light emitting elements LD may be electrically connected in parallel to each other between the 2-1-th alignment electrode ALE2_1 and the first alignment electrode ALE1 and between the first alignment electrode ALE1 and the 2-2-th alignment electrode ALE2_2.

The light emitting elements LD may be disposed at positions spaced from each other and aligned in substantially parallel to each other. A distance by which the light emitting elements LD are spaced from each other is not particularly limited. In one or more embodiments, a plurality of light emitting elements LD may be disposed adjacent to each other to form a group, and a plurality of additional light emitting elements LD may be spaced from each other at regular intervals to form another group. The light emitting elements LD may be aligned in one direction with an uneven density.

The light emitting elements LD may be input (or supplied) to the pixel area PXA (or the emission area EMA) by an inkjet printing scheme, a slit coating scheme, or other various schemes. For example, the light emitting elements LD may be mixed with a volatile solvent and then input (or supplied) to the pixel area PXA by an inkjet printing scheme or a slit coating scheme.

In one or more embodiments, the light emitting elements LD may include a first light emitting element LD1 and a second light emitting element LD2.

The first light emitting element LD1 may be aligned between the right side of the first alignment electrode ALE1 and the 2-1-th alignment electrode ALE2_1 and electrically connected to the first electrode PE1 and the intermediate electrode CTE. The second light emitting element LD2 may be aligned between the left side of the first alignment electrode ALE1 and the 2-2-th alignment electrode ALE2-2 and electrically connected to the intermediate electrode CTE and the second electrode PE2.

A plurality of first light emitting elements LD1 and a plurality of second light emitting elements LD2 may be provided. The first end EP1 of each of the first light emitting elements LD1 may be electrically connected to the first electrode PE1. The second end EP2 of each of the first light emitting elements LD1 may be electrically connected to the intermediate electrode CTE. The first end EP1 of each of the second light emitting elements LD2 may be electrically connected to the intermediate electrode CTE. The second end EP2 of each of the second light emitting elements LD2 may be electrically connected to the second electrode PE2.

The first light emitting elements LD1 may be connected in parallel to each other between the first electrode PE1 and the intermediate electrode CTE. The second light emitting elements LD2 may be connected in parallel to each other between the intermediate electrode CTE and the second electrode PE2.

The electrodes PE and the intermediate electrode CTE may be provided in at least the emission area EMA of the pixel PXL, and each may be provided at a position corresponding to at least one alignment electrode ALE and at least one light emitting element LD.

The electrodes PE may include a first electrode PE1 and a second electrode PE2 which are spaced from each other.

The first electrode PE1 (or the first pixel electrode) may be formed on the right side of the first alignment electrode ALE1 and the respective first ends EP1 of the first light emitting elements LD1, and thus electrically connected to the respective first ends EP1 of the first light emitting elements LD1. The first electrode PE1 may have a bar shape having a constant width in an extension direction thereof, e.g., the second direction DR2, but the present disclosure is not limited thereto.

The second electrode PE2 (or the second pixel electrode) may be formed on the 2-2-th alignment electrode ALE2_2 and the respective second ends EP2 of the second light emitting elements LD2, and thus electrically connected to the respective second ends EP2 of the second light emitting elements LD2. The second electrode PE2 may have a bar shape having a constant width in an extension direction thereof, e.g., the second direction DR2, but the present disclosure is not limited thereto.

The intermediate electrode CTE may be formed on the 2-1-th alignment electrode ALE2_1 and the respective second ends EP2 of the first light emitting elements LD1, and thus may be electrically connected to the respective second end EP2 of the first light emitting elements LD1. Furthermore, the intermediate electrode CTE may be formed on the left side of the first alignment electrode ALE1 and the respective first ends EP1 of the second light emitting elements LD2, and thus electrically connected to the respective first ends EP1 of the second light emitting elements LD2. The intermediate electrode CTE may be bent at least one or more times to enclose at least one side of the first electrode PE1.

The first light emitting element LD1 may be connected in series to the second light emitting element LD2 by the intermediate electrode CTE. The first electrode PE1 and the intermediate electrode CTE, along with the first light emitting elements LD1 connected in parallel therebetween, may form a first series set SET1 (refer to “SET1” of FIG. 4) of the emission component EMU. The intermediate electrode CTE and the second electrode PE2, along with the second light emitting elements LD2 connected in parallel therebetween, may form a second series set (refer to “SET2” of FIG. 4) of the emission component EMU. The first electrode PE1 may be an anode of the emission component EMU. The second electrode PE2 may be a cathode of the emission component EMU.

In one or more embodiments, the first electrode PE1 may be electrically connected to some components of the pixel circuit PXC through a first contact hole CH1 and a first opening OPN1 that overlap each other in the non-emission area NEA. For example, the first electrode PE1 may be electrically connected to the upper electrode (refer to “UE” in FIG. 4) of the storage capacitor (refer to “Cst” in FIG. 4) of the pixel circuit PXC through a first contact hole CH1 and the first opening OPN1. In one or more embodiments, the first contact hole CH1 and the first opening OPN1 may be formed by removing certain areas of a plurality of insulating layers between the first electrode PE1 and the upper electrode UE.

The second electrode PE2 may be electrically connected to the second power line PL2 through the second contact hole CH2 and a third opening OPN3 that overlap each other in the non-emission area NEA. The second contact hole CH2 and the third opening OPN3 may be formed by removing certain areas of a plurality of insulating layers between the second electrode PE2 and the second power line PL2.

The first light emitting element LD1 and the second light emitting element LD2 may be connected in series to each other through the intermediate electrode CTE between the first electrode PE1 and the second electrode PE2. In this way, the light emitting elements LD aligned in the emission area EMA may be connected in a series/parallel combination structure to form the emission component EMU of the pixel PXL.

The upper electrode UE of the pixel circuit PXC and the first electrode PE1 of the emission component EMU are brought into direct contact with and connected to each other through the first contact hole CH1 and the first opening OPN1. The second power line PL2 and the second electrode PE2 of the emission component EMU are brought into direct contact with and connected to each other through the second contact hole CH2 and the third opening OPN3. Hence, during each frame period, driving current may flow from the first electrode PE1 to the second electrode PE2 via the first light emitting element LD1, the intermediate electrode CTE, the second light emitting element LD2.

In one or more embodiments, the first electrode PE1 and the second electrode PE2 may be used as driving electrodes configured to drive the light emitting elements LD.

Hereinafter, the stacked structure of the pixel PXL in accordance with the foregoing embodiment will be mainly described with reference to FIGS. 6 to 9.

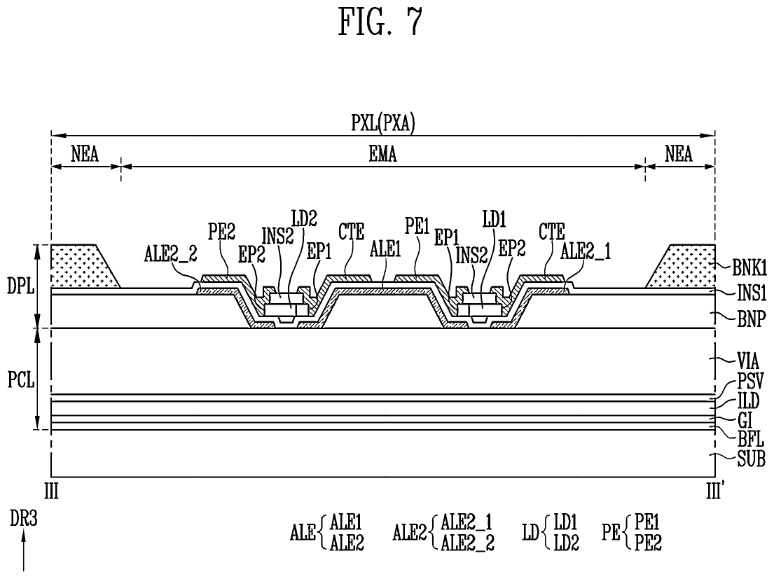

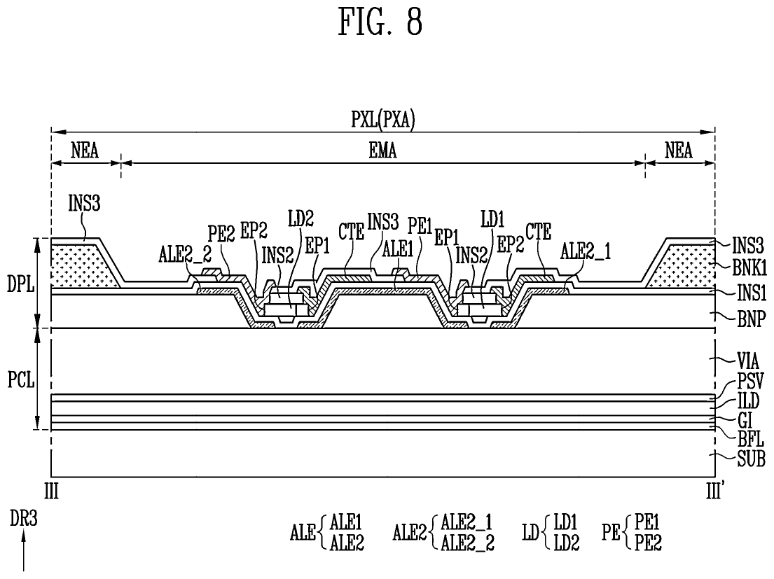

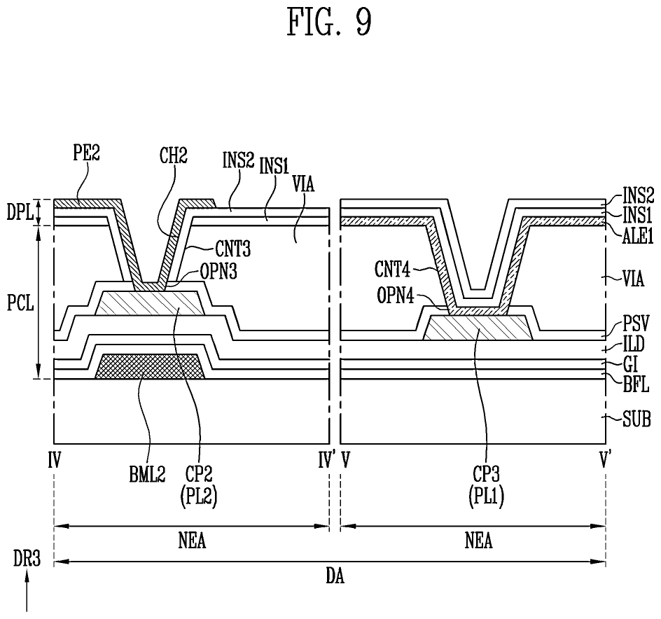

FIG. 6 is a schematic sectional view taken along the line II-II′ of FIG. 5. FIGS. 7 and 8 are schematic sectional views taken along the line III-III′ of FIG. 5. FIG. 9 is a schematic sectional view taken along the line IV-IV′ and line V-V′ of FIG. 5.

One or more embodiments of FIG. 8 refers to a modification of the embodiment of FIG. 7 pertaining both to the step of forming the intermediate electrode CTE and to whether the third insulating layer INS3 is present. For example, in FIG. 8, there is illustrated one or more embodiments where the first and second electrodes PE1 and PE2 are formed after the intermediate electrode CTE and the third insulating layer INS3 are formed.

The following description related to embodiments of FIGS. 6 to 9 will be focused on differences from the above-mentioned embodiments so as to avoid redundant description.

Referring to FIGS. 1 to 9, the pixel PXL may include a substrate SUB, a pixel circuit layer PCL, and a display element layer DPL.

The pixel circuit PXC including circuit elements may be disposed in the pixel circuit layer PCL. The emission component EMU including the light emitting element LD electrically connected to the pixel circuit PXC may be disposed in the display element layer DPL.

The pixel circuit layer PCL and the display element layer DPL may be disposed on one surface of the substrate SUB and overlap each other. For example, in the pixel area PXA of the substrate SUB, the pixel circuit layer PCL may be disposed on one surface of the substrate SUB, and the display element layer DPL may be disposed on the pixel circuit layer PCL. However, relative positions of the pixel circuit layer PCL and the display element layer DPL on the substrate SUB may be changed depending on embodiments. In case that the pixel circuit layer PCL and the display element layer DPL are separated from each other as separate layers and overlap each other, layout space sufficient to form each of the pixel circuit PXC and the emission component EMU on a plane may be secured. In one or more embodiments, the pixel circuit layer PCL and the display element layer DPL may be disposed on the same plane without overlapping each other.

The substrate SUB may include transparent insulating material. The substrate SUB may be a rigid substrate or a flexible substrate.

In each pixel area PXA of the pixel circuit layer PCL, circuit elements for forming the pixel circuit PXC of the corresponding pixel PXL and signal lines electrically connected to the circuit elements may be disposed. Furthermore, the alignment electrodes ALE, the light emitting elements LD, and/or the electrodes PE that form the emission component EMU of the corresponding pixel PXL may be disposed in each pixel area PXA of the display element layer DPL.

The pixel circuit layer PCL may include at least one or more insulating layers as well as including the circuit elements and the signal lines. For example, the pixel circuit layer PCL may include a buffer layer BFL, a gate insulating layer GI, an interlayer insulating layer ILD, a passivation layer PSV, and a via layer VIA which are successively stacked on the substrate SUB in the third direction DR3.

The buffer layer BFL may be disposed on the overall surface of the substrate SUB. The buffer layer BFL may prevent impurities from diffusing into a transistor T included in the pixel circuit PXC. The buffer layer BFL may be an inorganic insulating layer including inorganic material. For example, the buffer layer BFL may include at least one of silicon nitride (SiNₓ), silicon oxide (SiOₓ), silicon oxynitride (SiOₓN_{y}), and/or aluminum oxide (AlOₓ), but the present disclosure is not limited thereto. The buffer layer BFL may be provided in the form of a single layer structure, or provided in the form of a multilayer structure having at least two or more layers. In case that the buffer layer BFL is provided in the form of a multilayer structure, the respective layers may be formed of the same material or different materials. The buffer layer BFL may be omitted depending on the material of the substrate SUB or processing conditions.

The gate insulating layer GI may be disposed on the overall surface of the buffer layer BFL, but the present disclosure is not limited thereto. In one or more embodiments, the gate insulating layer GI may be partially disposed on the buffer layer BFL. The gate insulating layer GI may include the same material as that of the buffer layer BFL, or include suitable (or selected) material from among the materials provided as examples for the constituent materials of the buffer layer BFL. The gate insulating layer GI may be an inorganic insulating layer including inorganic material.

The interlayer insulating layer ILD may be provided and/or formed on the overall surface of the gate insulating layer GI. The interlayer insulating layer ILD may include the same material as that of the buffer layer BFL, or include one or more suitable (or selected) materials from among the materials provided as examples for the constituent materials of the buffer layer BFL, but the present disclosure is not limited thereto.

The passivation layer PSV may be provided and/or formed on the overall surface of the interlayer insulating layer ILD. The passivation layer PSV may include the same material as that of the buffer layer BFL, or include one or more suitable (or selected) materials from among the materials provided as examples for the constituent materials of the buffer layer BFL, but the present disclosure is not limited thereto. The passivation layer PSV may partially have an opening through which some of the circuit elements disposed in the pixel circuit layer PCL are exposed. For example, the passivation layer PSV may partially have openings, including the first opening OPN1 through which a certain area of the upper electrode UE (or a first conductive pattern CP1) is exposed, the second opening OPN2 through which a certain area of the second power line PL2 is exposed, the third opening OPN3 through which a certain area of a second conductive pattern CP2 is exposed, and the fourth opening OPN4 through which a certain area of a third conductive pattern CP3 is exposed.

The via layer VIA may be provided and/or formed on the overall surface of the passivation layer PSV. The via layer VIA may be formed of a single layer including an organic layer, or multiple layers having double or more layers. In one or more embodiments, the via layer VIA may be provided in a shape including an inorganic layer and an organic layer disposed on the inorganic layer. In case that the via layer VIA is formed of multiple layers having double or more layers, the organic layer included in the via layer VIA may be located on the uppermost layer of the via layer VIA. The via layer VIA may include at least one of polyacrylates resin, epoxy resin, phenolic resin, polyamides resin, polyimides rein, unsaturated polyesters resin, poly-phenylen ethers resin, poly-phenylene sulfides resin, and/or benzocyclobutene resin.

In one or more embodiments, the via layer VIA may partially have an opening through which some of the circuit elements disposed in the pixel circuit layer PCL are exposed. For example, the via layer VIA may partially have openings, including a first contactor CNT1 through which a certain area of the upper electrode UE (or the first conductive pattern CP1) is exposed, the second contactor CNT2 through which a certain area of the second power line PL2 is exposed, a third contactor CNT3 through which a certain area of the second conductive pattern CP2 is exposed, and the fourth contactor CNT4 through which a certain area of the third conductive pattern CP3 is exposed. For example, the first contactor CNT1 of the via layer VIA may correspond to the first opening OPN1 of the passivation layer PSV. The second contactor CNT2 of the via layer VIA may correspond to the second opening OPN2 of the passivation layer PSV. The third contactor CNT3 of the via layer VIA may correspond to the third opening OPN3 of the passivation layer PSV. The fourth contactor CNT4 of the via layer VIA may correspond to the fourth opening OPN4 of the passivation layer PSV.

In one or more embodiments, opposite side surfaces of the via layer VIA that defines the first contactor CNT1 therebetween are positioned outside opposite side surfaces of the passivation layer PSV that defines the first opening OPN1 therebetween, thus allowing the opposite side surfaces of the passivation layer PSV to be exposed. Furthermore, opposite side surfaces of the via layer VIA that defines the third contactor CNT3 therebetween are positioned outside opposite side surfaces of the passivation layer PSV that defines the third opening OPN3 therebetween, thus allowing the opposite side surfaces of the passivation layer PSV to be exposed. Opposite side surfaces of the via layer VIA that defines the second contactor CNT2 therebetween may be positioned on the same lines as opposite side surfaces of the passivation layer PSV that defines the second opening OPN2 therebetween. Opposite side surfaces of the via layer VIA that defines the fourth contactor CNT4 therebetween may be positioned on the same lines as opposite side surfaces of the passivation layer PSV that defines the fourth opening OPN4 therebetween.

The via layer VIA may be used as a planarization layer formed to mitigate a step difference which occurs due to components of the pixel circuit PXC that are disposed under the via layer VIA in the pixel circuit layer PCL.

The pixel circuit layer PCL may include at least one or more conductive layers disposed between the aforementioned insulating layers. For example, the pixel circuit layer PCL may include a first conductive layer disposed between the substrate SUB and the buffer layer BFL, a second conductive layer disposed on the gate insulating layer GI, and a third conductive layer disposed on the interlayer insulating layer ILD. However, the insulating layers and the conductive layers included in the pixel circuit layer PCL are not limited to the aforementioned elements. In one or more embodiments, in addition to the insulating layers and the conductive layers, other insulating layers and other conductive layers may be provided in the pixel circuit layer PCL.

The first conductive layer may be formed as a single layer made of a single material or a combination selected from the group consisting of copper (Cu), molybdenum (Mo), tungsten (W), neodymium (Nd), titanium (Ti), aluminum (AI), silver (Ag), and an alloy thereof. Furthermore, to reduce line resistance, the first conductive layer may have a double-layer or multi-layer structure formed of molybdenum (Mo), titanium (Ti), copper (Cu), aluminum (AI), and/or silver (Ag), which is low-resistance material. Each of the second and third conductive layers may include the same material as that of the first conductive layer, or include one or more suitable materials from among the materials provided as examples for the constituent material of the first conductive layer, but the present disclosure is not limited thereto.

The pixel circuit PXC disposed in the pixel circuit layer PCL may include at least one transistor T. The transistor T may include one of the first, second, and third transistors T1, T2, and T3 described with reference to FIG. 4. For example, the transistor T may be the first transistor T1 described with reference to FIG. 4.

The transistor T may include a semiconductor pattern SCP, a gate electrode GE overlapping a portion of the semiconductor pattern SCP in the third direction DR3, and source and drain electrodes SE and DE connected to the semiconductor pattern SCP.

The gate electrode GE may be formed on the gate insulating layer GI. The gate electrode GE may be a second conductive layer disposed between the gate insulating layer GI and the interlayer insulating layer ILD. The gate electrode GE may overlap a portion of the semiconductor pattern SCP. For example, the gate electrode GE may overlap an active pattern of the semiconductor pattern SCP.

The semiconductor pattern SCP may be provided and/or formed on the buffer layer BFL. For example, the semiconductor pattern SCP may be disposed between the buffer layer BFL and the gate insulating layer GI. The semiconductor pattern SCP may be a semiconductor layer formed of poly silicon, amorphous silicon, an oxide semiconductor, and/or the like. The semiconductor pattern SCP may include an active pattern, a first contact area, and a second contact area. The active pattern, the first contact area, and the second contact area each may be formed of a semiconductor layer that is either undoped or doped with impurities. For example, each of the first contact area and the second contact area may be formed of a semiconductor layer that is doped with impurities, and the active pattern may be formed of an undoped semiconductor layer.

The active pattern of the semiconductor pattern SCP may be an area which overlaps the gate electrode GE of the transistor T, and may form a channel area of the transistor T. The first contact area of the semiconductor pattern SCP may contact one end of the active pattern. Furthermore, the first contact area may be connected to the source electrode SE. The second contact area of the semiconductor pattern SCP may contact a remaining end of the active pattern. Furthermore, the second contact area may be connected to the drain electrode DE.

The source electrode SE may be positioned on the interlayer insulating layer ILD. The source electrode SE may contact the first contact area of the semiconductor pattern SCP through a contact hole that passes through the gate insulating layer GI and the interlayer insulating layer ILD.

The drain electrode DE may be positioned on the interlayer insulating layer ILD. The drain electrode DE may be disposed on the interlayer insulating layer ILD at a position spaced from the source electrode SE. The drain electrode DE may contact the second contact area of the semiconductor pattern SCP through a contact hole that passes through the gate insulating layer GI and the interlayer insulating layer ILD.

A first bottom metal pattern BML1 may be disposed under the transistor T.

The first bottom metal pattern BML1 may be formed of a first conductive layer disposed between the substrate SUB and the buffer layer BFL. The first bottom metal pattern BML1 may be electrically connected to the transistor T. The first bottom metal pattern BML1 may be electrically connected to the semiconductor pattern SCP of the transistor T and stabilize the channel area of the transistor T. Furthermore, the first bottom metal pattern BML1 is electrically connected to the transistor T, whereby the first bottom metal pattern BML1 can be prevented from floating.

A second bottom metal pattern BML2, the first power line PL1, the second power line PL2, and conductive patterns may be disposed in the pixel circuit layer PCL. The conductive patterns may include the first conductive pattern CP1, the second conductive pattern CP2, and the third conductive pattern CP3 disposed at positions spaced from each other.

The second bottom metal pattern BML2 may be formed of a first conductive layer disposed between the substrate SUB and the buffer layer BFL. The second bottom metal pattern BML2 may be disposed between the substrate SUB and the buffer layer BFL to overlap the second conductive pattern CP2 in the third direction DR3.

The first conductive pattern CP1, the second power line PL2, the second conductive pattern CP2, and the third conductive pattern CP3 may be formed of the third conductive layer disposed between the interlayer insulating layer ILD and the passivation layer PSV.

In one or more embodiments, the first conductive pattern CP1 may be an upper electrode UE (of a capacitor, e.g., Cst) electrically connected to the source electrode SE of the transistor T. The third conductive pattern CP3 may be a first power line PL1 to which a voltage of the first driving power supply (refer to “VDD” of FIG. 4) is to be applied. The second conductive pattern CP2 may be a second power line PL2 to which a voltage of the second driving power supply (refer to “VSS” of FIG. 4) is to be applied, but the present disclosure is not limited thereto. In one or more embodiments, the second conductive pattern CP2 may be formed separately from the second power line PL2, and then electrically connected to the second power line PL2.

The upper electrode UE (or the first conductive pattern CP1) may be connected to the first electrode PE1 of the display element layer DPL in such a way that the upper electrode US directly contacts the first electrode PE1 through the first opening OPN1 of the passivation layer PSV and the first contact hole CH1 of the second insulating layer INS2.

The second power line PL2 may be connected to the 2-1-th alignment electrode ALE2_1 of the display element layer DPL in such a way that the second power line PL2 directly contacts the 2-1-th alignment electrode ALE2_1 through the second opening OPN2 of the passivation layer PSV and the second contactor CNT2 of the via layer VIA.

The second conductive pattern CP2 may be connected to the second electrode PE2 of the display element layer DPL in such a way that the second conductive pattern CP2 directly contacts the second electrode PE2 through the third opening OPN3 of the passivation layer PSV and the second contact hole CH2 of the second insulating layer INS2.

The second opening OPN2 of the passivation layer PSV and the second contactor CNT2 of the via layer VIA may expose one area of the second power line PL2. The third opening OPN3 of the passivation layer PSV, the third contactor CNT3 of the via layer VIA, and the second contact hole CH2 of the second insulating layer INS2 may expose one area of the second conductive pattern CP2 (or another area of the second power line PL2).

The third conductive pattern CP3 (or the first power line PL1) may be connected to the first alignment electrode ALE1 of the display element layer DPL in such a way that the third conductive pattern CP3 directly contacts the first alignment electrode ALE1 through the fourth opening OPN4 of the passivation layer PSV and the fourth contactor CNT4 of the via layer VIA.

The display element layer DPL may be located on the via layer VIA.

The display element layer DPL may include the first and second alignment electrodes ALE1 and ALE2, the light emitting elements LD, the first and second electrodes PE1 and PE2, and the intermediate electrode CTE that are disposed in the emission area EMA. Furthermore, the display element layer DPL may further include insulating patterns and/or insulating layers that are successively disposed on one surface of the pixel circuit layer PCL (or the via layer VIA). For example, the display element layer DPL may further include bank patterns BNP, a first insulating layer INS1, a first bank BNK1, and a second insulating layer INS2.

The bank pattern BNP may be disposed on the via layer VIA of the pixel circuit layer PCL. Each of the bank patterns BNP may be formed of a separate pattern that is individually disposed under each of the first and second alignment electrodes ALE1 and ALE2 such that the separate pattern overlaps a portion of a corresponding one of the first and second alignment electrodes ALE1 and ALE2. For example, the bank pattern BNP may be formed of a separate pattern that is individually disposed under each of the first alignment electrode ALE1, the 2-1-th alignment electrode ALE2_1, and the 2-2-th alignment electrode ALE2_2 such that the separate pattern overlaps a portion of a corresponding one of the first alignment electrode ALE1, the 2-1-th alignment electrode ALE2_1, and the 2-2-th alignment electrode ALE2_2.

The bank pattern BNP may protrude upward in the third direction DR3 on one surface of the via layer VIA of the pixel circuit layer PCL. Hence, one area of each of the first and second alignment electrodes ALE1 and ALE2 disposed on the bank pattern BNP may protrude in the third direction DR3 (or the thickness direction of the substrate SUB).

The bank pattern BNP may be an inorganic insulating layer including inorganic material or an organic insulating layer including organic material. In one or more embodiments, the bank pattern BNP may include an organic layer having a single layer structure and/or an inorganic layer having a single layer structure, but the present disclosure is not limited thereto. In one or more embodiments, the bank pattern BNP may be provided in the form of a multilayer structure formed by stacking at least one organic insulating layer and at least one inorganic insulating layer. However, the material of the bank pattern BNP is not limited to the foregoing embodiment. In one or more embodiments, the bank pattern BNP may include a conductive material (or a conductive substance). The shape of the bank pattern BNP may be changed in various ways within a range in which efficiency of light emitted from the light emitting element LD can be enhanced.

The bank pattern BNP may be used as a reflector. For example, the bank pattern BNP, along with the first and second alignment electrodes ALE1 and ALE2 disposed thereover, may be used as a reflector to guide light emitted from the light emitting element LD in a desired direction, thus enhancing the light output efficiency of the pixel PXL.

The first and second alignment electrodes ALE1 and ALE2 may be positioned on the bank pattern BNP.

The first and second alignment electrodes ALE1 and ALE2 may be positioned on the pixel circuit layer PCL (or the via layer VIA) and the bank pattern BNP.

The 2-2-th alignment electrode ALE2_2, the first alignment electrode ALE1, and the 2-1-th alignment electrode ALE2_1 may be arranged in one direction, e.g., a horizontal direction, intersecting the third direction DR3, in a sectional view. The 2-2-th alignment electrode ALE2_2, the first alignment electrode ALE1, and the 2-1-th alignment electrode ALE2_1 may be disposed on the same plane, and have the same thickness in the third direction DR3. The 2-2-th alignment electrode ALE2_2, the first alignment electrode ALE1, and the 2-1-th alignment electrode ALE2_1 may be concurrently (e.g., simultaneously) formed through the same process, or may be successively formed.

The first and second alignment electrodes ALE1 and ALE2 may be formed of material having a reflectivity to allow light emitted from the light emitting elements LD to travel in an image display direction (or a frontal direction, e.g., the third direction DR3) of the display device DD. For example, each of the first and second alignment electrodes ALE1 and ALE2 may be formed of conductive material (or substance). The conductive material may include opaque metal that is suitable for reflecting, in the image display direction of the display device DD, light emitted from the light emitting elements LD.

Each of the first and second alignment electrodes ALE1 and ALE2 may have a single-layer structure, but is not limited thereto. In one or more embodiments, each of the first and second alignment electrodes ALE1 and ALE2 may be provided and/or formed in a multilayer structure formed by stacking at least two or more materials from among metals, alloys, conductive oxides, and conductive polymers. Each of the first and second alignment electrodes ALE1 and ALE2 may be provided in the form of a multilayer structure including at least double layers to reduce or minimize a distortion due to a signal delay when signals are transmitted to the first end EP1 and the second end EP2 of each of the light emitting elements LD.

In case that each of the first and second alignment electrodes ALE1 and ALE2 are formed of conductive material having a reflectivity, light emitted from each of the light emitting elements LD may more reliably travel in the image display direction of the display device DD (e.g., the third direction DR3).

The first insulating layer INS1 may be positioned on the first and second alignment electrodes ALE1 and ALE2.

The first insulating layer INS1 may be disposed on the first and second alignment electrodes ALE1 and ALE2, the bank pattern BNP, and the via layer VIA. The first insulating layer INS1 may partially have an opening in at least the non-emission area NEA, thus allowing components disposed underneath to be exposed. For example, the first insulating layer INS1 may have openings in certain areas respectively corresponding to the first and third contactors CNT1 and CNT3 of the via layer VIA.

The first insulating layer INS1 may be formed of an inorganic insulating layer made of inorganic material, but the present disclosure is not limited thereto. The first insulating layer INS1 may be provided to have a single-layer or multilayer structure. In the case in which the first insulating layer INS1 is provided in the form of a multilayer structure, the first insulating layer INS1 may have a distributed Bragg reflector structure formed by alternately stacking first inorganic layers and second inorganic layers which have different refractive indexes.

The first insulating layer INS1 may be disposed over the entirety of the emission area EMA and the non-emission area NEA of each pixel PXL, but the present disclosure is not limited thereto. In one or more embodiments, the first insulating layer INS1 may be disposed in only a specific area of each pixel PXL, e.g., in only the emission area EMA.

The first bank BNK1 may be disposed on the first insulating layer INS1.

The first bank BNK1 may be disposed on the first insulating layer INS1 in the non-emission area NEA. The first bank BNK1 may be formed between adjacent pixels PXL to enclose the emission area EMA of each pixel PXL, thus partitioning (or defining) the emission area EMA of the corresponding pixel PXL. The first bank BNK1 may be surface-treated so that at least one surface thereof has hydrophobicity. For example, the first bank BNK1 may be surface-treated to have hydrophobicity by plasma before the light emitting elements LD are aligned, but the present disclosure is not limited thereto.

The first bank BNK1 and the bank pattern BNP may be formed through different processes and provided in different layers, but the present disclosure is not limited thereto. In one or more embodiments, the first bank BNK1 and the bank pattern BNP may be formed through different processes and provided in the same layer, or may be formed through the same process and provided in the same layer.

The light emitting elements LD may be supplied to and aligned in the emission area EMA of the pixel PXL in which the first insulating layer INS1 and the first bank BNK1 are formed. For example, the light emitting elements LD may be supplied to the emission area EMA through an inkjet printing scheme or the like. The light emitting elements LD may be aligned on the first insulating layer INS1 between the alignment electrodes ALE by an electric field formed by a signal (or an alignment signal) applied to each of the alignment electrodes ALE. For instance, the light emitting elements LD supplied to the emission area EMA may be arranged such that the first ends EP1 face the first alignment electrode ALE1, and the second ends EP2 face the second alignment electrode ALE2.

The light emitting elements LD may include a first light emitting element LD1 and a second light emitting element LD2.

The first light emitting element LD1 may be arranged between the right side of the first alignment electrode ALE1 and the 2-1-th alignment electrode ALE2_1. The first light emitting element LD1 may include a first end EP1 that overlaps the right side of the first alignment electrode ALE1, and a second end EP2 that overlaps the 2-1-th alignment electrode ALE2_1.

The second light emitting element LD2 may be arranged between the left side of the first alignment electrode ALE1 and the 2-2-th alignment electrode ALE2_2. The second light emitting element LD2 may include a first end EP1 that overlaps the left side of the first alignment electrode ALE1, and a second end EP2 that overlaps the 2-2-th alignment electrode ALE2_2.

A second insulating layer INS2 may be positioned on each of the first and second light emitting elements LD1 and LD2. The second insulating layer INS2 that is positioned on each of the first and second light emitting elements LD1 and LD2 allows the first end EP1 and the second end EP2 of each of the first and second light emitting elements LD1 and LD2 to be exposed to the outside. The second insulating layer INS2 may be formed on the first insulating layer INS1 in the non-emission area NEA and partially have an opening, thus allowing some components disposed underneath to be exposed. For example, the second insulating layer INS2 may be partially open to include the first contact hole CH1 corresponding to the first opening OPN1 of the passivation layer PSV so that one area of the upper electrode UE (or the first conductive pattern CP1) can be exposed, and may be partially open to include the second contact hole CH2 corresponding to the third opening OPN3 of the passivation layer PSV so that one area of the second conductive pattern CP2 (or another area of the second power line PL2) can be exposed.

The second insulating layer INS2 may include an inorganic insulating layer including inorganic material, or an organic insulating layer. For example, the second insulating layer INS2 may include an inorganic insulating layer suitable for protecting the active layer (refer to “12” in FIG. 1) of each of the first and second light emitting elements LD1 and LD2 from external oxygen, water, and/or the like. However, the present disclosure is not limited thereto. The second insulating layer INS2 may be formed of an organic insulating layer including organic material, depending on design conditions, etc. of the display device DD to which the first and second light emitting elements LD1 and LD2 are applied. The second insulating layer INS2 may have a single-layer or multilayer structure.

The second insulating layer INS2 is formed on the first and second light emitting elements LD1 and LD2 that are completely aligned in the emission area EMA of each pixel PXL, thus preventing the first and second light emitting elements LD1 and LD2 from being removed from aligned positions.

Different electrodes from among the electrodes PE and the intermediate electrode CTE may be formed on the first and second ends EP1 and EP2 of the first and second light emitting elements LD1 and LD2 that are not covered with the second insulating layer INS2. For example, the first electrode PE1 may be formed on the first end EP1 of the first light emitting element LD1. The intermediate electrode CTE may be formed on the second end EP2 of the first light emitting element LD1. The intermediate electrode CTE may be formed on the first end EP1 of the second light emitting element LD2. The second electrode PE2 may be formed on the second end EP2 of the second light emitting element LD2.

The first electrode PE1 may be disposed over the first alignment electrode ALE1 to overlap the right side of the first alignment electrode ALE1. The second electrode PE2 may be disposed over the 2-2-th alignment electrode ALE2_2 to overlap the 2-2-th alignment electrode ALE2_2. The intermediate electrode CTE may be disposed over each of the left side of the first alignment electrode ALE1 and the 2-1-th alignment electrode ALE2_1.

In one or more embodiments, the first electrode PE1 may be brought into direct contact and connected to the upper electrode UE (or the first conductive pattern CP1) through the first contact hole CH1 of the second insulating layer INS2, the first contactor CNT1 of the via layer VIA, and the first opening OPN1 of the passivation layer PSV. The second electrode PE2 may be brought into direct contact with and connected to the second conductive pattern CP2 (or the second power line PL2) through the second contact hole CH2 of the second insulating layer INS2, the third contactor CNT3 of the via layer VIA, and the third opening OPN3 of the passivation layer PSV.

In one or more embodiments, the first electrode PE1, the intermediate electrode CTE, and the second electrode PE2 may be formed in the same layer or different layers. For example, relative positions and/or a formation sequence of the first electrode PE1, the intermediate electrode CTE, and the second electrode PE2 may be changed in various ways depending on the embodiment.

In one or more embodiments of FIG. 7, the first electrode PE1, the intermediate electrode CTE, and the second electrode PE2 may be disposed on the same layer in the display element layer DPL, and may be concurrently (e.g., simultaneously) or sequentially formed. For example, the first electrode PE1 may be positioned adjacent to one side surface of the second insulating layer INS2 on the first light emitting element LD1. The intermediate electrode CTE may be positioned adjacent to another side surface of the second insulating layer INS2 on the first light emitting element LD1. The intermediate electrode CTE may be positioned adjacent to one side surface of the second insulating layer INS2 on the second light emitting element LD2. The second electrode PE2 may be positioned adjacent to another side surface of the second insulating layer INS2 on the second light emitting element LD2. In case that the electrodes disposed on the first end EP1 and the second end EP2 of each light emitting element LD are disposed on the same layer and concurrently (e.g., simultaneously) formed, a process of fabricating the pixel PXL may be facilitated, and the process efficiency may be enhanced.

In one or more embodiments of FIG. 8, the intermediate electrode CTE may be first formed on the second insulating layer INS2. The intermediate electrode CTE may directly contact each of the second end EP2 of the first light emitting element LD1 and the first end EP1 of the second light emitting element LD2 and thus may be connected between the first light emitting element LD1 and the second light emitting element LD2. Thereafter, the third insulating layer INS3 may be formed in the emission area EMA to cover the intermediate electrode CTE.

The third insulating layer INS3 may be disposed on the intermediate electrode CTE and thus cover the intermediate electrode CTE (or prevent the intermediate electrode CTE from being exposed to the outside), thus preventing corrosion or the like of the intermediate electrode CTE. The third insulating layer INS3 may be formed of an inorganic insulating layer including inorganic material, or an organic insulating layer including organic material. For example, the third insulating layer INS3 may include at least one of silicon nitride SiNₓ, silicon oxide SiOₓ, silicon oxynitride SiOₓN_{y}, and/or metal oxide such as aluminum oxide AlOₓ, but the present disclosure is not limited thereto. The third insulating layer INS3 may have a single-layer or multilayer structure.

The first electrode PE1 and the second electrode PE2 may be formed on the third insulating layer INS3. The first electrode PE1 may directly contact the first end EP1 of the first light emitting element LD1. The second electrode PE2 may directly contact the second end EP2 of the second light emitting element LD2.

As illustrated in the embodiment of FIG. 8, in case that the electrodes disposed on the first end EP1 and the second end EP2 of each light emitting element LD are disposed on different layers, the electrodes may be reliably electrically separated from each other so that a short-circuit defect can be prevented from occurring between the electrodes.

The first electrode PE1, the second electrode PE2, and the intermediate electrode CTE may be formed of various transparent conductive materials to allow light emitted from each of the light emitting elements LD to travel in the image display direction (e.g., in the third direction DR3) of the display device DD without optical loss. For example, the first electrode PE1, the second electrode PE2, and the intermediate electrode CTE may include at least one of various transparent conductive materials including indium tin oxide (ITO), indium zinc oxide (IZO), zinc oxide (ZnOx), indium gallium zinc oxide (IGZO), and/or indium tin zinc oxide (ITZO), and may be substantially transparent or translucent to satisfy a certain transmittancy (or transmittance). The materials of the first electrode PE1, the second electrode PE2, and the intermediate electrode CTE are not limited to those of the foregoing embodiments.

In one or more embodiments, at least one overcoat layer (e.g., a layer for planarizing the upper surface of the display element layer DPL) may be further disposed over the first electrode PE1, the intermediate electrode CTE, and the second electrode PE2.

In one or more embodiments, the display element layer DPL of each pixel PXL may optionally include an optical layer including certain particles that convert light emitted from the light emitting elements LD to light with excellent color reproducibility.

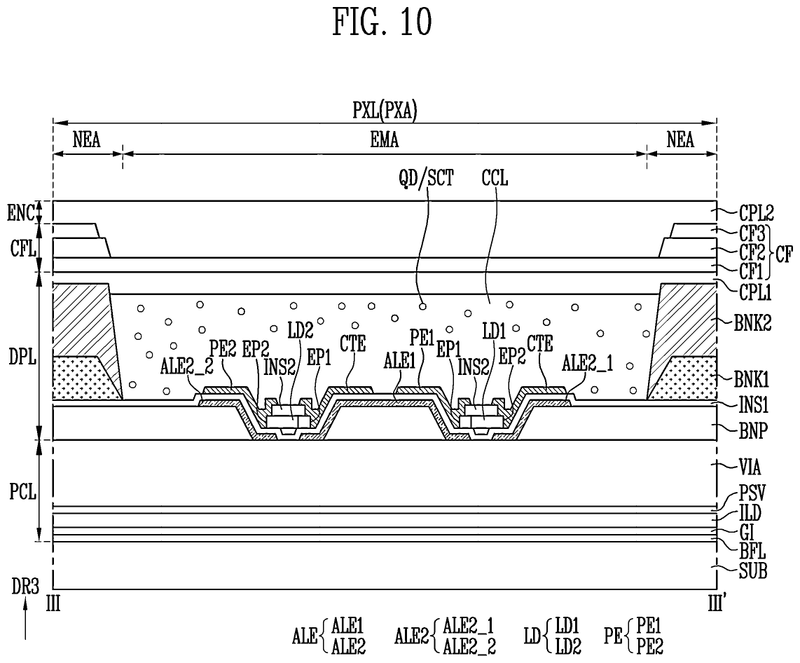

Hereinafter, an example of the pixel PXL including the optical layer will be described with reference to FIG. 10.

FIG. 10 illustrates the pixel PXL in accordance with one or more embodiments, and is a schematic sectional view taken along the line III-III′ of FIG. 5.

With regard to the embodiment of FIG. 10, the following description will be focused on differences from that of the foregoing embodiments, to avoid redundant explanation.

Referring to FIGS. 1 to 5 and 10, each pixel PXL may include a substrate SUB, a pixel circuit layer PCL, a display element layer DPL, a color filter layer CFL, and an encapsulation layer ENC.

The display element layer DPL may include a color conversion layer CCL positioned on the first electrode PE1, the intermediate electrode CTE, and the second electrode PE2 to correspond to the emission area EMA, and a second bank BNK2 positioned on the first bank BNK1 to correspond to the non-emission area NEA. Furthermore, the display element layer DPL may include a first capping layer CPL1 disposed on the second bank BNK2 and the color conversion layer CCL.

The second bank BNK2 may be a dam structure, which encloses the emission area EMA of the pixel PXL and defines a supply position of the color conversion layer CCL, thus eventually defining the emission area EMA. The second bank BNK2 may include light shielding material. For example, the second bank BNK2 may include at least one light blocking material and/or reflective material, and allow light emitted from the color conversion layer CCL to reliably travel in the image display direction of the display device DD (e.g., the third direction DR3), thus enhancing the light output efficiency of the color conversion layer CCL.

The color conversion layer CCL may be formed on the first electrode PE1, the intermediate electrode CTE, and the second electrode PE2 of each pixel PXL in the emission area EMA enclosed by the second bank BNK2. The color conversion layer CCL may include color conversion particles QD corresponding to a specific color. For example, the color conversion layer CCL may include color conversion particles QD, which convert light emitted from the light emitting elements LD to light of a specific color (or light with excellent color reproducibility).

In the case where the pixel PXL is a red pixel, the color conversion layer CCL of the pixel PXL may include color conversion particles QD formed of red quantum dots that convert light emitted from the light emitting elements LD to red light.

In the case where the pixel PXL is a green pixel, the color conversion layer CCL of the pixel PXL may include color conversion particles QD formed of green quantum dots that convert light emitted from the light emitting elements LD to green light.

In the case where the pixel PXL is a blue pixel, the color conversion layer CCL of the pixel PXL may include color conversion particles QD formed of blue quantum dots that convert light emitted from the light emitting elements LD to blue light. In the case in which the pixel PXL is a blue pixel, in one or more embodiments, there may be provided a light scattering layer having light scattering particles SCT, in place of the color conversion layer CCL including the color conversion particles QD. For example, in case that the light emitting elements LD emit blue-based light, the pixel PXL may include a light scattering layer including light scattering particles SCT. The light scattering layer may be omitted depending on embodiments. In the case where the pixel PXL is a blue pixel, a transparent polymer may be provided in lieu of the color conversion layer CCL.

The first capping layer CPL1 may be provided on the overall surface of the display area (refer to “DA” in FIG. 3), in which the pixel PXL is disposed, to cover the second bank BNK2 and the color conversion layer CCL. The first capping layer CPL1 may be an inorganic insulating layer including inorganic material. The first capping layer CPL1 may include at least one of silicon nitride (SiNₓ), silicon oxide (SiOₓ), silicon oxynitride (SiOₓN_{y}), aluminum oxide (AlOₓ), and/or the like. The first capping layer CPL1 may cover the entireties of the second bank BNK2 and the color conversion layer CCL and thus prevent external water, oxygen, and/or the like from being drawn into the color conversion layer CCL.

In one or more embodiments, the first capping layer CPL1 may mitigate a step difference formed by components disposed underneath and have an even surface. For example, the first capping layer CPL1 may include an organic insulating layer including organic material, but the present disclosure is not limited thereto.

The color filter layer CFL may be disposed on the first capping layer CPL1.

The color filter layer CFL may include a color filter CF corresponding to the emission area EMA of each pixel PXL. For example, the color filter layer CFL may include a first color filter CF1 disposed on the color conversion layer CCL of one pixel PXL (hereinafter, referred to as “first pixel”), a second color filter CF2 disposed on the color conversion layer CCL of an adjacent pixel (hereinafter, referred to as “second pixel”) adjacent to the first pixel PXL, and a third color filter CF3 disposed on the color conversion layer of an adjacent pixel adjacent to the second pixel.

The first, second, and third color filters CF1, CF2, and CF3 may be disposed in the non-emission area NEA and overlap each other, thus functioning as a light blocking component for preventing optical interference between adjacent pixels PXL from occurring. Each of the first, second, and third color filters CF1, CF2, and CF3 may include color filter material that allows a specific color of light converted by the corresponding color conversion layer CCL to selectively pass therethrough. For example, the first color filter CF1 may be a red color filter, the second color filter CF2 may be a green color filter, and the third color filter CF3 may be a blue color filter, but the present disclosure is not limited thereto.

The encapsulation layer ENC may be disposed on the color filter layer CFL.

The encapsulation layer ENC may include a second capping layer CPL2. The second capping layer CPL2 may be an inorganic insulating layer including inorganic material or an organic insulating layer including organic material. The second capping layer CPL2 may cover the entireties of components disposed underneath and prevent external water, moisture, and/or the like from being introduced into the color filter layer CFL. In one or more embodiments, the encapsulation layer ENC may be used as a planarization layer for mitigating a step difference caused by the components of the color filter layer CFL positioned under the encapsulation layer ENC.

The second capping layer CPL2 may have a multilayer structure. For example, the second capping layer CPL2 may be formed of at least two inorganic insulating layers, and at least one organic insulating layer interposed between the at least two inorganic insulating layers. Here, the constituent material and/or structure of the second capping layer CPL2 may be changed in various ways. In some embodiments, at least one overcoat layer, at least one filler layer, and/or at least another substrate may be further disposed over the second capping layer CPL2.

In the pixel PXL in accordance with the foregoing embodiment, the color conversion layer CCL and the color filter layer CFL may be disposed on the light emitting elements LD through successive processes so that light having excellent light reproducibility can be emitted through the color conversion layer CCL and the color filter layer CFL, whereby the light output efficiency can be enhanced.

In one or more embodiments, the color conversion layer CCL and the color filter layer CFL may be formed, through successive processes, on one surface of a substrate (e.g., an upper substrate) separately provided from the substrate SUB (e.g., a lower substrate), and then coupled to the substrate SUB by an adhesive or the like.

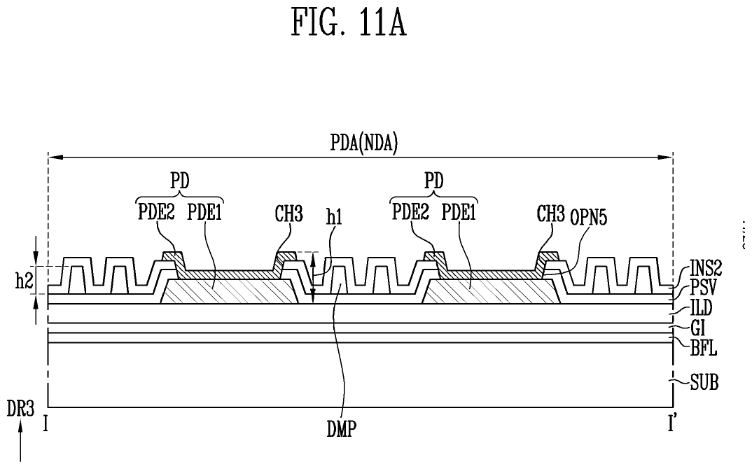

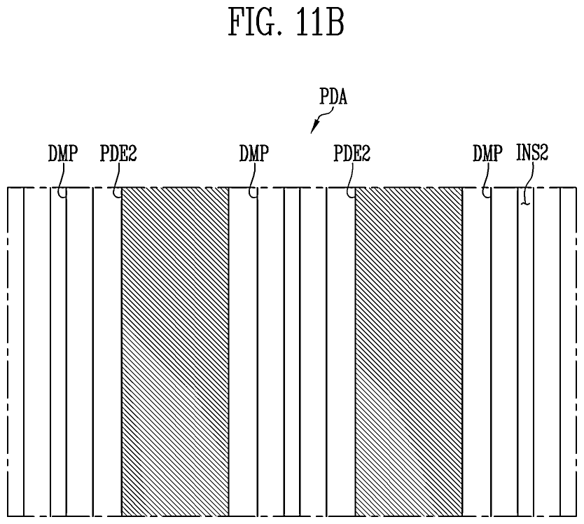

FIG. 11A is a schematic sectional view taken along the line I-I′ of FIG. 3. FIG. 11B is a schematic top view of the pad area PDA of FIG. 11A.

The description with reference to FIGS. 11A and 11B will be focused on differences from the above-mentioned embodiments so as to avoid redundant description.

Referring to FIGS. 3, 11A, and 11B, a plurality of pads PD may be disposed in the pad area PDA (or the non-display area NDA).

Each of the pads PD may include a first pad electrode PDE1 and a second pad electrode PDE2.

The first pad electrode PDE1 may be disposed on the interlayer insulating layer ILD. The first pad electrode PDE1 may be provided in the same layer as the first conductive pattern CP1, the second conductive pattern CP2, and the third conductive pattern CP3 that have been described with reference to FIGS. 6 to 10. The first pad electrode PDE1, the first conductive pattern CP1, the second conductive pattern CP2, and the third conductive pattern CP3 may be formed through the same process or may be formed through successive processes, and may include the same material.

The second pad electrode PDE2 may be disposed on the second insulating layer INS2. The second pad electrode PDE2 may be provided in the same layer as the first and second electrodes PE1 and PE2 described with reference to FIGS. 6 to 10. The second pad electrode PDE2, the first electrode PE1, and the second electrode PE2 may be formed through the same process or may be formed through successive processes, and may include the same material. The second pad electrode PDE2 may overlap the first pad electrode PDE1, with the passivation layer PSV and the second insulating layer INS2 interposed therebetween.

The second pad electrode PDE2 may be electrically connected to the first pad electrode PDE1 in such a way that the second pad electrode PDE2 directly contacts the first pad electrode PDE1 through a fifth opening OPN5 of the passivation layer PSV and a third contact hole CH3 of the second insulating layer INS2. The fifth opening OPN5 of the passivation layer PSV may correspond to the third contact hole CH3 of the second insulating layer INS2. In this case, opposite side surfaces of the passivation layer PSV that define the fifth opening OPN5 therebetween may be positioned on the same lines as opposite side surfaces of the second insulating layer INS2 that define the third contact hole CH3 therebetween.

In one or more embodiments, a dummy pattern DMP may be positioned in the pad area PDA. The dummy pattern DMP may be positioned in the pad area PDA without overlapping each of the pads PD. For example, the dummy pattern DMP may be positioned on an edge of each of the pads PD. In detail, the dummy pattern DMP may be positioned between two adjacent pads PD and disposed adjacent to the outermost pad PD from among the pads PD. The dummy pattern DMP may be positioned in the same layer as the via layer VIA in the display area DA, and may include the same material as the via layer VIA. The dummy pattern DMP may comprise a plurality of dummy patterns DMP. Each dummy pattern DMP may have a second height h2 in the third direction DR3. The second height h2 may be different from a first height h1 of each of the pads PD. For example, the second height h2 may be less than the first height h1. If the second height h2 of the dummy pattern DMP is greater than the first height h1 of each of the pads PD, the second pad electrode PDE2 may not adhere with a conductive adhesive component, thus causing contact failure between the second pad electrode PDE2 and the conductive adhesive component.

The pads PD may be bonded to the conductive adhesive component through an outer lead bonding (OLB) process. Hence, the pads PD may be electrically connected to an external circuit substrate by the conductive adhesive component. The conductive adhesive component may, for example, be an anisotropic conductive film including conductive balls formed in an adhesive film having adhesive properties. In the OLB process, the conductive balls of the conductive adhesive component and the second pad electrode PDE2 of each of the pads PD may be bonded together under pressure applied thereto. Here, crack defects in the pad area PDA may occur depending on factors such as the magnitude of the applied pressure and/or material characteristics of the components positioned in the pad area PDA. The dummy pattern DMP may be provided to reduce or prevent direct impacts of the pressure applied during the OLB process on the components positioned in the pad area PDA, such as the second pad electrode PDE2, and the inorganic insulating layer formed of inorganic material. In one or more embodiments, the dummy pattern DMP may disperse or absorb some of the pressure applied during the OLB process, thus reducing or minimizing crack defects in the pad area PDA. If the crack defects are reduced or minimized, the reliability of the display device DD may be enhanced.

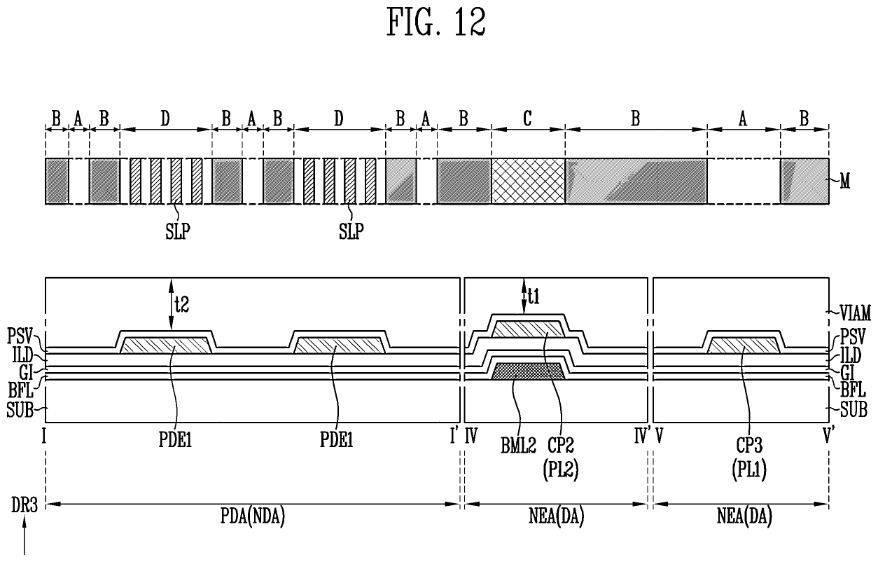

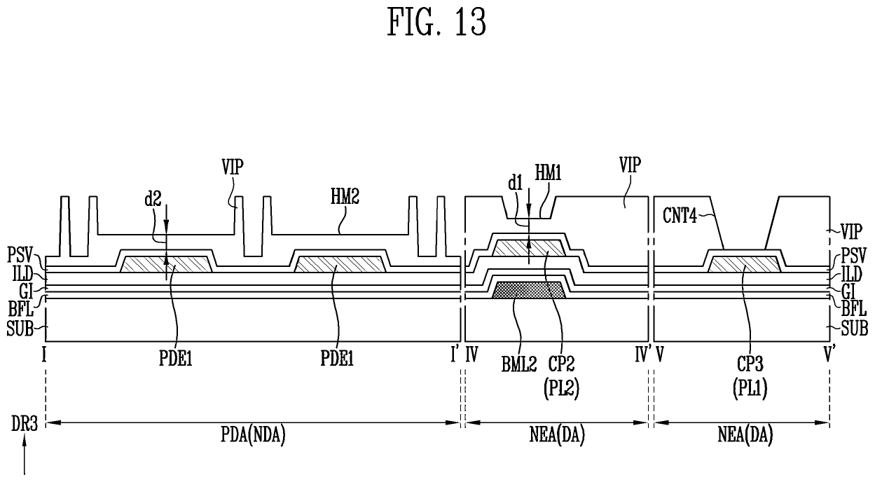

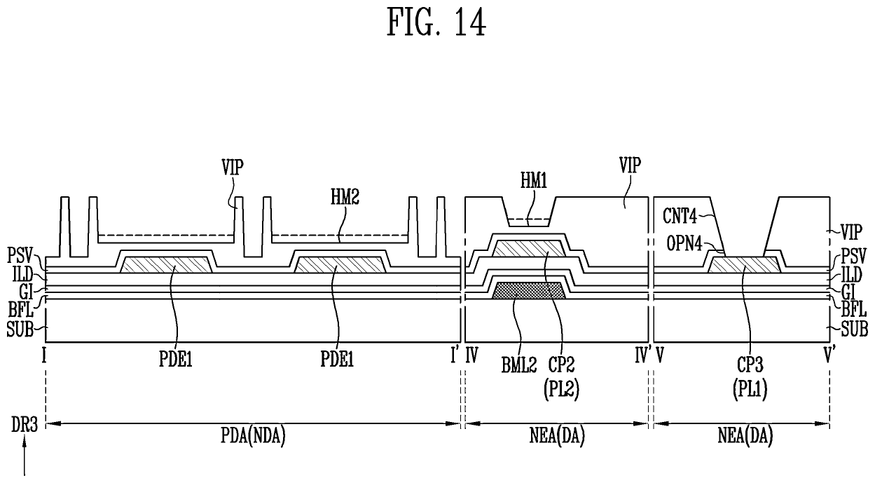

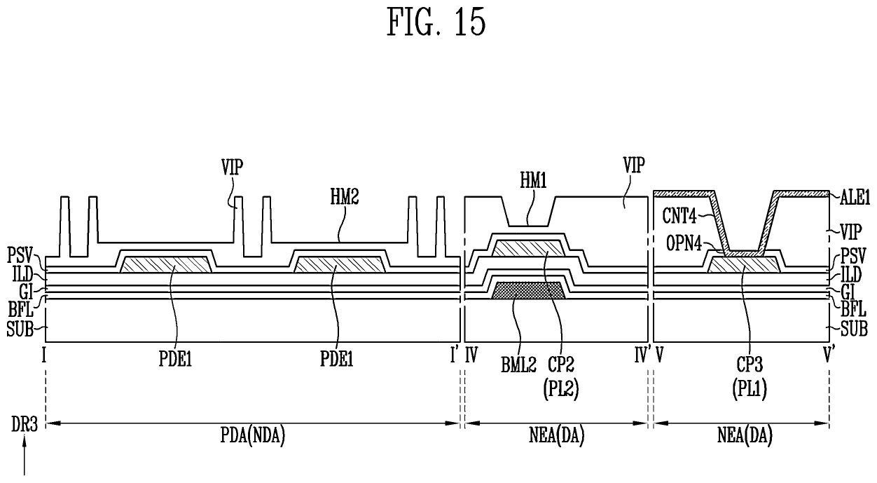

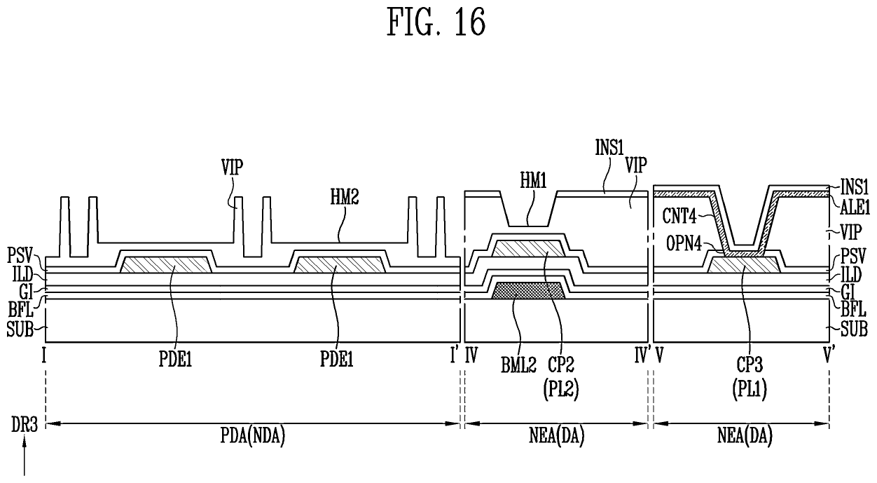

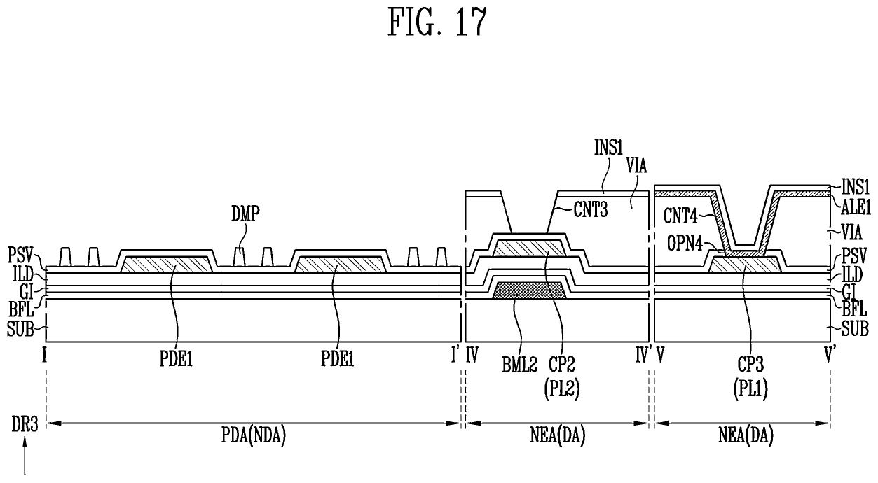

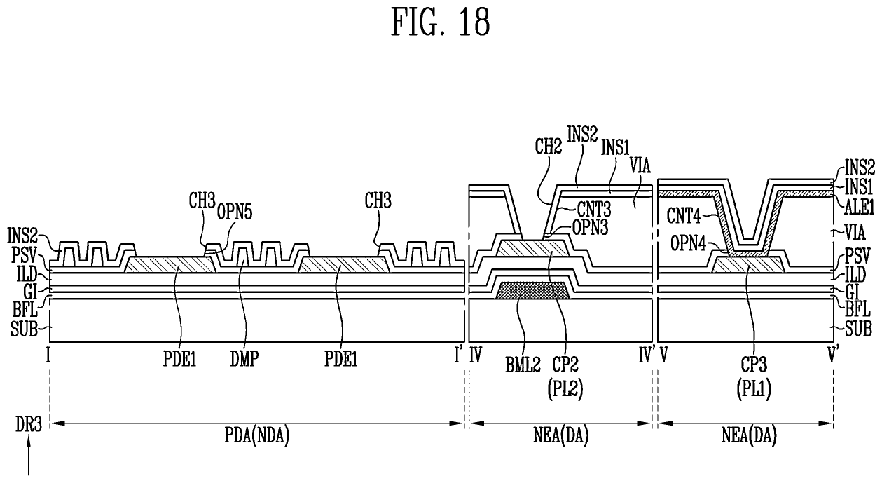

Hereinafter, a method of fabricating the display device DD in accordance with one or more embodiments will be described with reference to FIGS. 12 to 18.

FIGS. 12 to 18 are schematic sectional views for sequentially describing a method of fabricating the display device illustrated in FIGS. 9 and 11A.

In one or more embodiments of FIGS. 12 to 18, there is illustrated the case where the steps of fabricating the display device are sequentially performed according to the sectional views, but without changing the technical scope of the present disclosure, some steps illustrated as being successively performed may be concurrently (e.g., simultaneously) performed, the sequence of the steps may be changed, some steps may be skipped, or an additional step may be further included between the steps.

The description with reference to FIGS. 12 to 18 will be focused on differences from the above-mentioned embodiments so as to avoid redundant description.

Referring to FIGS. 1 to 12, the first and second bottom metal patterns BML1 and BML2, the transistor T, the second power line PL2, and the first to third conductive patterns CP1, CP2, and CP3 are formed on the substrate SUB in the display area DA (or the pixel area PXA). The first pad electrode PDE1 is formed on the substrate SUB in the pad area PDA (or the non-display area NDA).

The passivation layer PSV is formed on the transistor T, the first to third conductive patterns CP1, CP2, and CP3, and the first pad electrode PDE1. A via material layer VIAM is formed on the passivation layer PSV.

The via material layer VIAM may have an even (or uniform) upper surface regardless of the area, but may have varying thickness (for example, in the third direction DR3) in different areas. For instance, as illustrated in FIG. 12, a thickness t1 of the via material layer VIAM on the second conductive pattern CP2 may be less than a thickness t2 of the via material layer VIAM on the first pad electrode PDE1 and a thickness t2 of the via material layer VIAM on the third conductive pattern CP3. This is because the second conductive pattern CP2 overlaps the second bottom metal pattern BML2 positioned underneath, forming a step difference in thickness identical to the thickness of the second bottom metal pattern BML2, whereby a surface (or an upper surface) of the second conductive pattern CP2 is positioned closer to an upper surface of the via material layer VIAM than are the first pad electrode PDE1 and the third conductive pattern CP3.

Photoresist is deposited on the via material layer VIAM, and a mask M is placed thereon. The mask M may include a halftone mask capable of adjusting light transmission for each area. The mask M may include a first portion A, a second portion B, a third portion C, and a fourth portion D. The first portion A may be a transparent portion that completely transmits light. The second portion B may be a blocking portion that completely blocks light. The third portion C may be a semi-transparent portion with adjusted light transmission. The fourth portion D may be a slit pattern portion with higher light transmission than the third portion C. In one or more embodiments, the fourth portion D may include at least two or more slit patterns SLP.

Referring to FIGS. 1 to 13, a photolithography process using the mask M may be performed to form a via pattern VIP including the second contactor (refer to “CNT2” in FIG. 6), the fourth contactor CNT4, a first stepped portion HM1, and a second stepped portion HM2.

Each of the second and fourth contactors CNT2 and CNT4 may correspond to the first portion A of the mask M. The first stepped portion HM1 may correspond to the third portion C of the mask M. The second stepped portion HM2 may correspond to the fourth portion D of the mask M. Remaining areas of the via pattern VIP, other than the second and fourth contactors CNT2 and CNT4, the first stepped portion HM1, and the second stepped portion HM2, may correspond to the second portion B of the mask M.

The second contactor CNT2 may expose the passivation layer PSV on the second power line PL2. The fourth contactor CNT4 may expose the passivation layer PSV on the third conductive pattern CP3. The first stepped portion HM1 may be placed on the passivation layer PSV on the second conductive pattern CP2 that is positioned over the second bottom metal pattern BML2 and overlaps the second bottom metal pattern BML2 in the third direction DR3. The second stepped portion HM2 may be placed on the passivation layer PSV on the first pad electrode PDE1.

A thickness d1 of the via pattern VIP in the first stepped portion HM1 (hereinafter, referred to as “first thickness”) may be the same as a thickness d2 of the via pattern VIP in the second stepped portion HM2 (hereinafter, referred to as “second thickness”). In other words, a residue of the via material layer VIAM positioned on the passivation layer PSV on the second conductive pattern CP2 that overlaps the second bottom metal pattern BML2 may be the same as a residue of the via material layer VIAM positioned on the passivation layer PSV on the first pad electrode PDE1. The first thickness d1 (or the residue of the via material layer VIAM on the second conductive pattern CP2) and the second thickness d2 (or the residue of the via material layer VIAM on the first pad electrode PDE1) may be made the same by adjusting the distance between the slit patterns SLP provided in the fourth portion D of the mask M and the number of slit patterns SLP.

Although directly illustrated in the drawings, the first stepped portion HM1 of the via pattern VIP may be positioned on the passivation layer PSV on the first conductive pattern CP1 that is positioned on the first bottom metal pattern (refer to “BML1” in FIG. 6) in the display area DA and overlaps the first bottom metal pattern BML1.

Referring to FIGS. 1 to 14, during a dry etching process, the fourth opening OPN4 corresponding to the fourth contactor CNT4 is formed in the passivation layer PSV, thus exposing one area of the third conductive pattern CP3 positioned underneath. Furthermore, during the dry etching process, the second opening OPN2 corresponding to the second contactor CNT2 is formed in the passivation layer PSV, thus exposing one area of the second power line PL2 that is positioned underneath.

During the dry etching process, the passivation layer PSV may be partially removed to include the second opening OPN2 and the fourth opening OPN4.

After the dry etching process, the bank pattern (refer to “BNP” in FIG. 6) is formed on the via pattern VIP in the display area DA. The bank pattern BNP may be formed of an organic insulating substance including organic material.

During a process of forming the bank pattern BNP, a portion of the via pattern VIP may be removed. Hence, the first stepped portion HM1 may be positioned more adjacent to the passivation layer PSV. The second stepped portion HM2 may be positioned more adjacent to the passivation layer PSV.

Referring to FIGS. 1 to 15, the first alignment electrode ALE1 and the second alignment electrode (refer to “ALE2” in FIG. 6) are formed on the via pattern VIP.

The first alignment electrode ALE1 may contact the third conductive pattern CP3 exposed through the fourth contactor CNT4 and the fourth opening OPN4, and thus may be electrically connected to the third conductive pattern CP3. The third conductive pattern CP3 may be the first power line PL1.

The second alignment electrode ALE2 may contact the second power line PL2 exposed through the second contactor CNT2 and the second opening OPN2, and thus may be electrically connected to the second power line PL2.

Referring to FIGS. 1 to 16, after an insulating material layer is applied to the overall surfaces of the first alignment electrode ALE1, the second alignment electrode ALE2, the bank pattern BNP, and the via pattern VIP, a photolithography process is performed to form the first insulating layer INS1 that is partially open to expose some components positioned underneath.

The first insulating layer INS1 may partially have an opening to expose the first stepped portion HM1 in the display area DA. Furthermore, the first insulating layer INS1 may have an opening to expose the entirety of the via pattern VIP in the pad area PDA. In other words, the first insulating layer INS1 may not be disposed (or may be omitted) in the pad area PDA.

Referring to FIGS. 1 to 17, an ashing process using oxygen plasma is performed to completely remove the first stepped portion HM1 from the display area DA, thus forming the via layer VIA including the first contactor (refer to “CNT1” in FIG. 6) and the third contactor CNT3 that expose the passivation layer PSV positioned under the first stepped portion HM1.

During the ashing process, the second stepped portion HM2 is completely removed from the pad area PDA, thus exposing the passivation layer PSV positioned underneath. Furthermore, a portion of the via layer VIP positioned between the first pad electrodes PDE1 in the pad area PDA is removed, thus forming the dummy pattern DMP.

The via layer VIA in the pixel area PXA and the dummy pattern DMP in the pad area PDA may include the same material, and may be formed through the same process and provided in the same layer.

If the thickness of the first stepped portion HM1 of the via pattern VIP (or the residue of the via pattern VIP on the second conductive pattern CP2) and the thickness of the second stepped portion HM2 of the via pattern VIP (or the residue of the via pattern VIP on the first pad electrode PDE1) are the same, the first stepped portion HM1 and the second stepped portion HM2 may be concurrently (e.g., simultaneously) removed through the ashing process. As a result, the passivation layer PSV on the second conductive pattern CP2 and the passivation layer PSV on the first pad electrode PDE1 may be exposed to the outside. If the thickness of the first stepped portion HM1 of the via pattern VIP and the thickness of the second stepped portion HM2 of the via pattern VIP are different from each other, the first stepped portion HM1 and the second stepped portion HM2 may not be concurrently (e.g., simultaneously) removed through the ashing process, and at least one of the first and second stepped portions HM1 and HM2 may remain, preventing the passivation layer PSV positioned underneath from being exposed to the outside. For example, in the case where the second stepped portion HM2 of the via pattern VIP is not completely removed and remains, preventing the passivation layer PSV positioned underneath from being exposed to the outside, there may be contact failure in the pad area PDA because the first pad electrode PDE1 is not exposed to the outside during a subsequent process of forming the second insulating layer (refer to “INS2” in FIG. 6). Taking this into consideration, in the aforementioned embodiment, the thickness of the first stepped portion HM1 of the via pattern VIP and the thickness of the second stepped portion HM2 of the via pattern VIP may be made the same using the halftone mask M including the third portion C formed of a semi-transparent portion and the fourth portion D with the slit pattern SLP, thus enabling the first stepped portion HM1 and the second stepped portion HM2 to be concurrently (e.g., simultaneously) removed during the ashing process.

After the ashing process, the first bank (refer to “BNK1” in FIG. 6) is formed in the display area DA, and the first and second alignment electrodes ALE1 and ALE2 are respectively supplied with corresponding signals (e.g., alignment signals), thus forming an electric field between the first alignment electrode ALE1 and the second alignment electrode ALE2. In a state where the electric field is formed, ink containing light emitting elements (refer to “LD” in FIG. 5) is inputted into the display area DA using a method such as inkjet printing. The light emitting elements LD are aligned between the first alignment electrode ALE1 and the second alignment electrode ALE2. After the light emitting elements, LD are self-aligned, a solvent included in the ink may be removed by a volatilization scheme or other schemes.

Referring to FIGS. 1 to 18, after an insulating material layer is applied to the overall surfaces of the light emitting elements LD, the first bank BNK1, the first insulating layer INS1, the passivation layer PSV, and the dummy pattern DMP, a photolithography process is performed, thus forming the second insulating layer INS2 that is partially open to expose some components positioned underneath.

The second insulating layer INS2 may partially have an opening to include the second contact hole CH2 that exposes one area of the passivation layer PSV that is positioned in the third contactor CNT3 and exposed through the third contactor CNT3. The second insulating layer INS2 may partially have an opening to include the first contact hole CH1 that exposes one area of the passivation layer PSV that is positioned in the first contactor CNT1 of the via layer VIA and exposed through the first contactor CNT1. The second insulating layer INS2 may partially have an opening to expose the first ends EP1 and the second ends EP2 of the light emitting elements LD in the emission area (refer to “EMA” in FIG. 6) in the pixel area PXA. The second insulating layer INS2 may partially have an opening to include the third contact hole CH3 that exposes one area of the passivation layer PSV on the first pad electrode PDE1 in the pad area PDA.

During the process of forming the second insulating layer INS2, the first opening OPN1 of the passivation layer PSV is formed by removing one area of the passivation layer PSV that is exposed through the first contact hole CH1 of the second insulating layer INS2, the third opening OPN3 of the passivation layer PSV is formed by removing one area of the passivation layer PSV that is exposed through the second contact hole CH2 of the second insulating layer INS2, and the fifth opening OPN5 of the passivation layer PSV is formed by removing one area of the passivation layer PSV that is exposed through the third contact hole CH3 of the second insulating layer INS2.

In other words, the passivation layer PSV may partially have openings to include the first opening OPN1, the third opening OPN3, and the fifth opening OPN5 during the process of forming the second insulating layer INS2. One area of the first conductive pattern CP1 may be exposed to the outside through the first opening OPN1 of the passivation layer PSV. One area of the second conductive pattern CP2 may be exposed to the outside through the third opening OPN3 of the passivation layer PSV. One area of the first pad electrode PDE1 may be exposed to the outside through the fifth opening OPN5 of the passivation layer PSV.

After the second insulating layer INS2 is formed, the first electrode (refer to “PE1” in FIG. 6), the second electrode (refer to “PE2” in FIG. 6), and the intermediate electrode (refer to “CTE” in FIG. 6) may be formed in the pixel area PXA, and the second pad electrode PDE2 may be formed in the pad area PDA.

The first electrode PE1 may be electrically connected to the first conductive pattern CP1 (or the upper electrode UE) in such a way that the first electrode PE1 contacts the first conductive pattern CP1 through the first contact hole CH1 of the second insulating layer INS2, the first contactor CNT1 of the via layer VIA, and the first opening OPN1 of the passivation layer PSV.

The second electrode PE2 may be electrically connected to the second conductive pattern CP2 in such a way that the second electrode PE2 contacts the second conductive pattern CP2 through the second contact hole CH2 of the second insulating layer INS2, the third contactor CNT3 of the via layer VIA, and the third opening OPN3 of the passivation layer PSV.

The second pad electrode PDE2 may be electrically connected to the first pad electrode PDE1 in such a way that the second pad electrode PDE2 contacts the first pad electrode PDE1 through the third contact hole CH3 of the second insulating layer INS2 and the fifth opening OPN5 of the passivation layer PSV.

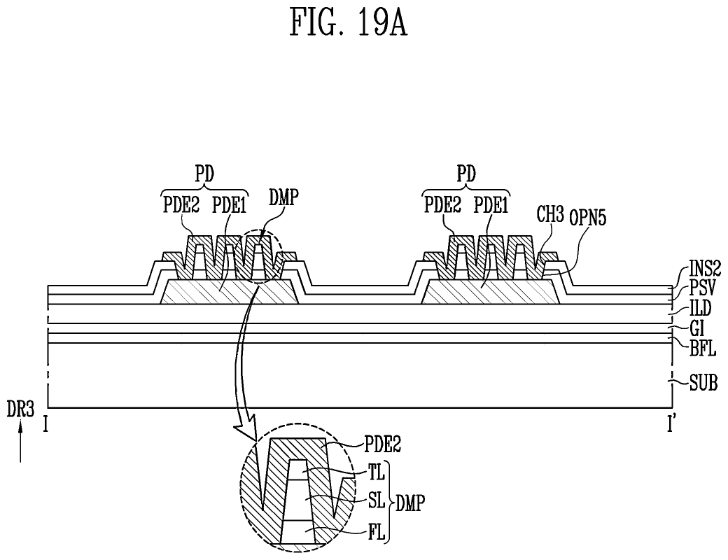

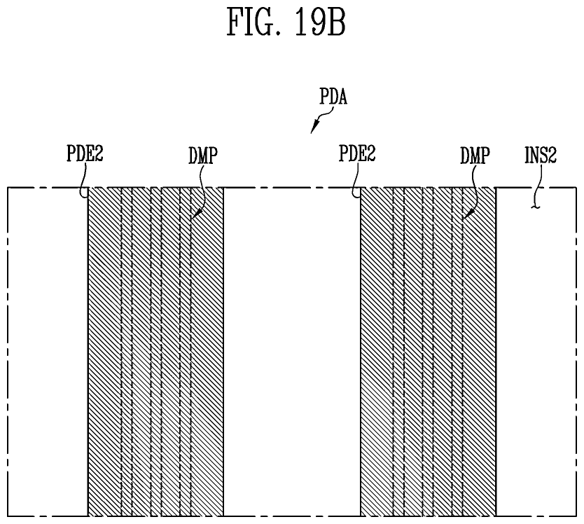

FIG. 19A is a schematic sectional view taken along the line I-I′ of FIG. 3. FIG. 19B is a schematic top view of the pad area PDA of FIG. 19A.

The description with reference to FIGS. 19A and 19B will be focused on differences from the above-mentioned embodiments so as to avoid redundant description.

Referring to FIGS. 3, 19A, and 19B, a plurality of pads PD may be disposed in the pad area PDA (or the non-display area NDA).

Each of the pads PD may include a first pad electrode PDE1 and a second pad electrode PDE2. The first pad electrode PDE1 may be disposed on the interlayer insulating layer ILD. The second pad electrode PDE2 may be disposed on the second insulating layer INS2. The second pad electrode PDE2 may be electrically connected to the first pad electrode PDE1 in such a way that the second pad electrode PDE2 directly contacts the first pad electrode PDE1 through the fifth opening OPN5 of the passivation layer PSV and the third contact hole CH3 of the second insulating layer INS2.

A dummy pattern DMP may be positioned in the pad area PDA. The dummy pattern DMP may be positioned on the first pad electrode PDE1 of each of the pads PD and overlap the first pad electrode PDE1 in the third direction DR3.

In one or more embodiments, the dummy pattern DMP may include a first layer FL, a second layer SL, and a third layer TL that are successively stacked from one surface of the first pad electrode PDE1 in the third direction DR3. The first layer FL may be positioned in the same layer as the passivation layer PSV, and may include the same material as the passivation layer PSV. The second layer SL may be positioned in the same layer as the via layer VIA in the display area DA (or the pixel area refer to “PXA” in FIG. 6), and may include the same material as the via layer VIA. The third layer TL may be positioned in the same layer as the first insulating layer (refer to “INS1” in FIG. 6), and may include the same material as the first insulating layer INS1.

The dummy pattern DMP may comprises a plurality of dummy patterns DMP. Each dummy pattern DMP may be positioned on the first pad electrode PDE1 and overlap the first pad electrode PDE1. The dummy patterns DMP may reduce or minimize arcing defects, which occur when charges are concentrated on the first pad electrode PDE1 that is largely (e.g., extensively) exposed to the outside during a process of forming the third contact hole CH3 in the second insulating layer INS2. If arcing defects on the first pad electrodes PDE1 are reduced or minimized, the reliability of the display device DD may be enhanced.

In one or more embodiments, the second pad electrode PDE2 may be disposed on the dummy pattern DMP and contact portions of the first pad electrode PDE1 that do not overlap the dummy pattern DMP, thus enabling electrical connection with the first pad PDE1.

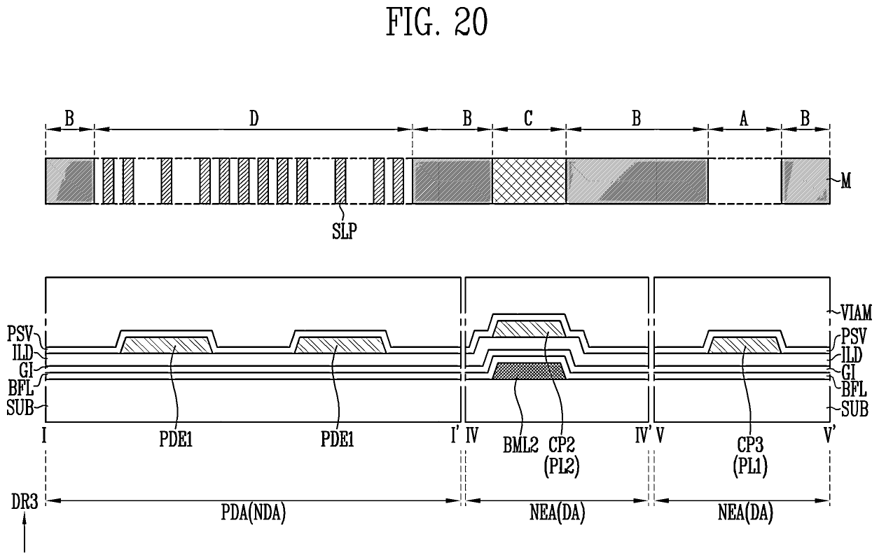

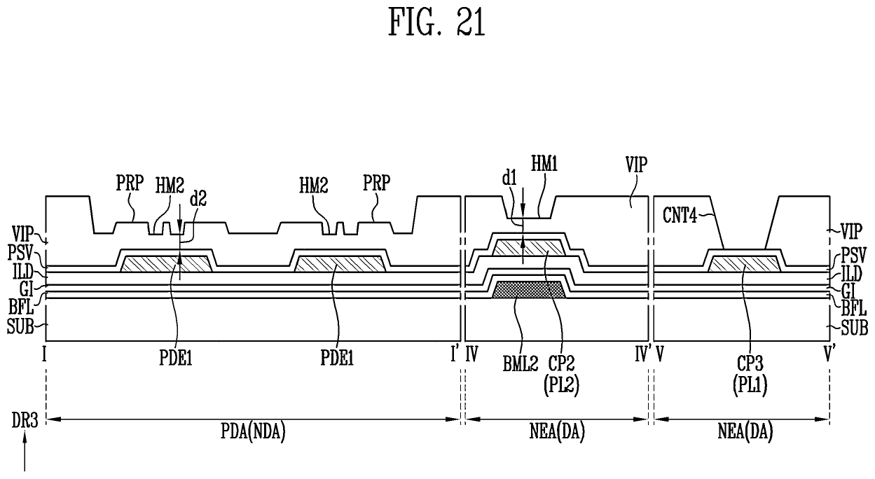

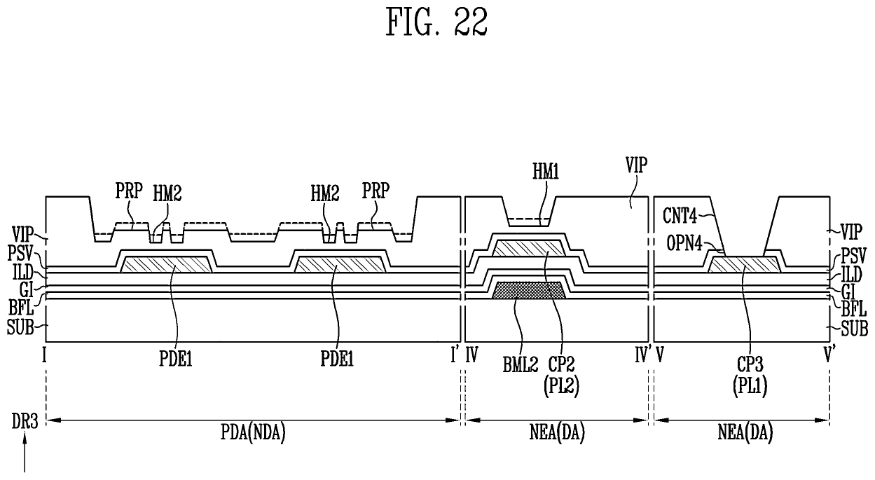

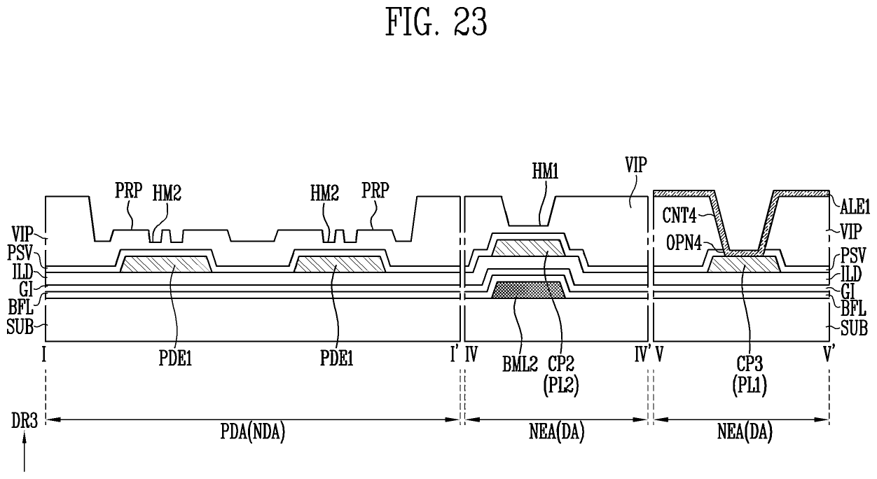

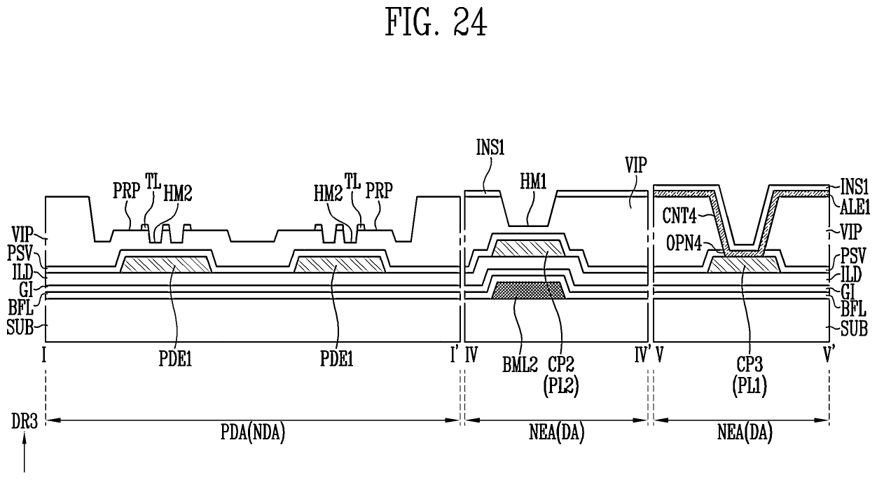

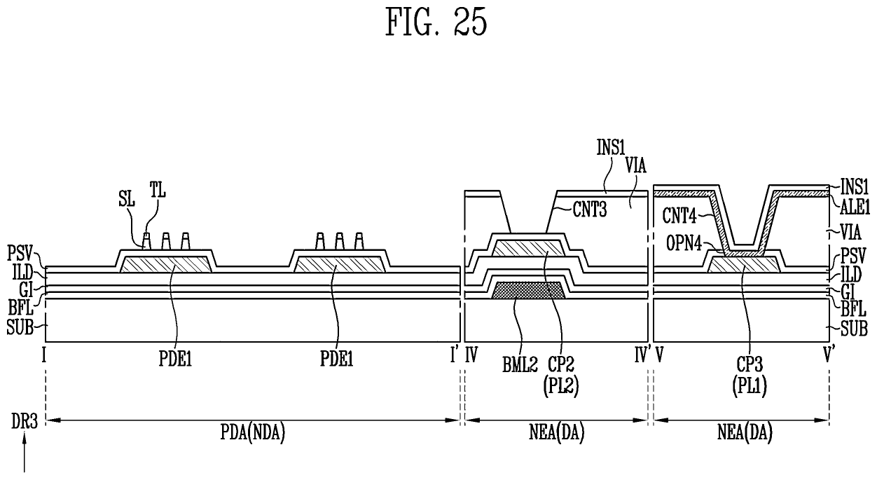

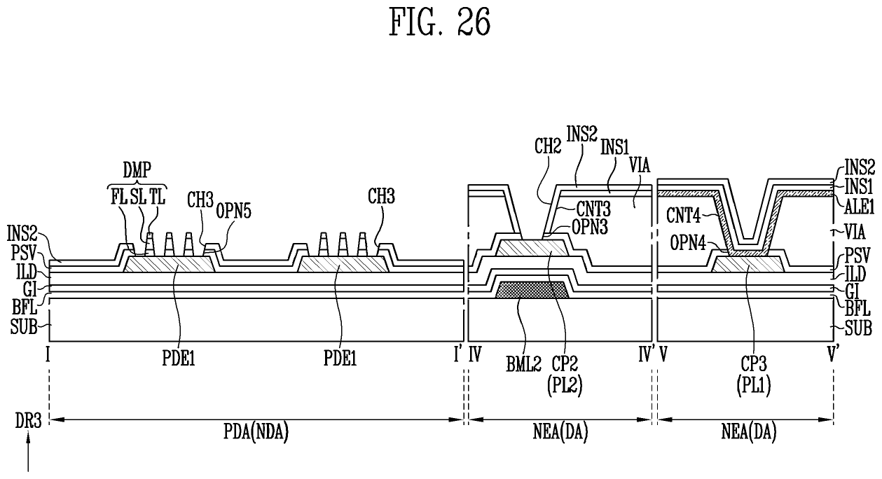

Hereinafter, a method of fabricating the display device (refer to “DD” in FIG. 3) in accordance with one or more embodiments will be described with reference to FIGS. 20 to 26.

FIGS. 20 to 26 are schematic sectional views for sequentially describing a method of fabricating the display device illustrated in FIGS. 9 and 19A.

The description with reference to FIGS. 20 to 26 will be focused on differences from the above-mentioned embodiments so as to avoid redundant description.

Referring to FIGS. 1 to 9 and 19A to 20, the first and second bottom metal layers BML1 and BML2, the transistor T, the second power line PL2, and the first to third conductive patterns CP1 to CP3 are formed on the substrate SUB in the display area DA (or the pixel area PXA). The first pad electrode PDE1 is formed on the substrate SUB in the pad area PDA (or the non-display area NDA).

The passivation layer PSV and the via material layer VIAM are successively formed on the transistor T, the first to third conductive patterns CP1, CP2, and CP3, and the first pad electrode PDE1. The via material layer VIAM may have an even (or uniform) upper surface regardless of the area, but may have varying thickness (for example, in the third direction DR3) in different areas.

Photoresist is deposited on the via material layer VIAM, and a mask M is placed thereon. The mask M may include a halftone mask capable of adjusting light transmission for each area. The mask M may include a first portion A, a second portion B, a third portion C, and a fourth portion D. The first portion A may be a transparent portion that completely transmits light. The second portion B may be a blocking portion that completely blocks light. The third portion C may be a semi-transparent portion with adjusted light transmission. The fourth portion D may be a slit pattern portion with higher light transmission than the third portion C. In one or more embodiments, the fourth portion D may include at least two or more slit patterns SLP. The fourth portion D may be positioned in the pad area PDA to correspond to both the via material layer VIAM on the first pad electrodes PDE1 and the via material layer VIAM on areas between the first pad electrodes PDE1.

In one or more embodiments, the distance between the slit patterns SLP (hereinafter, referred to as “first slit patterns”) corresponding to the via material layer VIAM on the first pad electrode PDE1 may be different from the distance between the slit patterns SLP (hereinafter, referred to as “second slit patterns”) corresponding to the via material layer VIAM on the areas between the first pad electrodes PDE1. For example, the distance between the first slit patterns SLP may be greater than the distance between the second slit patterns SLP. Because the distances between the slit patterns SLP of the mask M in the pad area PDA differ from each other, the via material layer VIAM positioned in the pad area PDA may have different thicknesses during a subsequent process.

Referring to FIGS. 1 to 9 and 19A to 21, a photolithography process using the mask M may be performed to form the via pattern VIP including the second contactor (refer to “CNT2” in FIG. 6), the fourth contactor CNT4, the first stepped portion HM1, the second stepped portion HM2, and a protrusion pattern PRP.

Each of the second and fourth contactors CNT2 and CNT4 may correspond to the first portion A of the mask M. The first stepped portion HM1 may correspond to the third portion C of the mask M. The second stepped portion HM2 and the protrusion pattern PRP may correspond to the fourth portion D of the mask M. Remaining areas of the via pattern VIP, other than the second and fourth contactors CNT2 and CNT4, the first stepped portion HM1, the second stepped portion HM2, and the protrusion pattern PRP, may correspond to the second portion B of the mask M.

The second contactor CNT2 may expose the passivation layer PSV on the second power line PL2. The fourth contactor CNT4 may expose the passivation layer PSV on the third conductive pattern CP3. The first stepped portion HM1 may be placed on the passivation layer PSV on the second conductive pattern CP2 that is positioned over the second bottom metal pattern BML2 and overlaps the second bottom metal pattern BML2. The protrusion pattern PRP may be positioned on the passivation layer PSV on one area of the first pad electrode PDE1 in the pad area PDA. The second stepped portion HM2 may be positioned between the protrusion patterns PRP in the pad area PDA and positioned on the passivation layer PSV on the remaining areas of the first pad electrode PDE1.

The thickness d1 of the via pattern VIP in the first stepped portion HM1 may be the same as the thickness d2 of the via pattern VIP in the second stepped portion HM2. In other words, the residue of the via material layer VIAM positioned on the passivation layer PSV on the second conductive pattern CP2 that overlaps the second bottom metal pattern BML2 may be the same as the residue of the via material layer VIAM positioned on the passivation layer PSV on the remaining areas of the first pad electrode PDE1 in the pad area PDA.

Referring to FIGS. 1 to 9 and 19A to 22, during a dry etching process, the fourth opening OPN4 corresponding to the fourth contactor CNT4 is formed in the passivation layer PSV, thus exposing one area of the third conductive pattern CP3 positioned underneath. Furthermore, during the dry etching process, the second opening OPN2 corresponding to the second contactor CNT2 is formed in the passivation layer PSV, thus exposing one area of the second power line PL2 that is positioned underneath.

After the dry etching process, the bank pattern (refer to “BNP” in FIG. 6) is formed on the via pattern VIP in the display area DA.

During a process of forming the bank pattern BNP, a portion of the via pattern VIP may be removed. As a result, each of the first stepped portion HM1, the second stepped portion HM2, and the protrusion pattern PRP may be positioned more adjacent to the passivation layer PSV.

Referring to FIGS. 1 to 9 and 19A to 23, the first alignment electrode ALE1 and the second alignment electrode (refer to “ALE2” in FIG. 6) are formed on the via pattern VIP.

The first alignment electrode ALE1 may contact the third conductive pattern CP3 exposed through the fourth contactor CNT4 and the fourth opening OPN4, and thus be electrically connected to the third conductive pattern CP3.

The second alignment electrode ALE2 may contact the second power line PL2 exposed through the second contactor CNT2 and the second opening OPN2, and thus be electrically connected to the second power line PL2.

Referring to FIGS. 1 to 9 and 19A to 24, after an insulating material layer is applied to the overall surfaces of the first alignment electrode ALE1, the second alignment electrode ALE2, the bank pattern BNP, and the via pattern VIP, a photolithography process is performed to form the first insulating layer INS1 and the third layer TL that are partially open to expose some components positioned underneath.

The first insulating layer INS1 may partially have an opening to expose the first stepped portion HM1 in the display area DA. The third layer TL may be disposed on the protrusion pattern PRP in the pad area PDA. The first insulating layer INS1 and the third layer TL may include the same material, and may be formed through the same process.

Referring to FIGS. 1 to 9 and 19A to 25, an ashing process using oxygen plasma is performed to completely remove the first stepped portion HM1 from the display area DA, thus forming the via layer VIA including the first contactor (refer to “CNT1” in FIG. 6) and the third contactor CNT3 that expose the passivation layer PSV positioned under the first stepped portion HM1.

During the ashing process, portions of the via pattern VIP that do not overlap the third layer TL in the pad area PDA is completely removed, thus allowing the passivation layer PSV positioned underneath to be exposed. During the ashing process, portions of the protrusion pattern PRP that are positioned under the third layer TL and overlap the third layer TL may remain on the passivation layer PSV rather than being removed, thus forming the second layer SL. The second layer SL may include the same material as the via layer VIA and may be formed in the same layer through the same process as the via layer VIA.

After the ashing process, the first bank (refer to “BNK1” in FIG. 6) is formed in the display area DA, and the first and second alignment electrodes ALE1 and ALE2 are respectively supplied with corresponding signals (e.g., alignment signals), thus forming an electric field between the first alignment electrode ALE1 and the second alignment electrode ALE2. In a state where the electric field is formed, ink containing light emitting elements (refer to “LD” in FIG. 5) is inputted into the display area DA. The light emitting elements LD are aligned between the first alignment electrode ALE1 and the second alignment electrode ALE2. After the light emitting elements LD are self-aligned, a solvent included in the ink may be removed by a volatilization scheme or other schemes.

Referring to FIGS. 1 to 9 and 19A to 26, after an insulating material layer is applied to the overall surfaces of the light emitting elements LD, the first bank BNK1, the first insulating layer INS1, the passivation layer PSV, and the second layer SL, a photolithography process is performed, thus forming the second insulating layer INS2 that is partially open to expose some components positioned underneath.

The second insulating layer INS2 may partially have an opening to include the second contact hole CH2 that exposes one area of the passivation layer PSV that is positioned in the third contactor CNT3 and exposed through the third contactor CNT3. The second insulating layer INS2 may partially have an opening to include the first contact hole CH1 that exposes one area of the passivation layer PSV that is positioned in the first contactor CNT1 and exposed through the first contactor CNT1. The second insulating layer INS2 may partially have an opening to expose the first ends EP1 and the second ends EP2 of the light emitting elements LD in the emission area (refer to “EMA” in FIG. 6) in the pixel area PXA. The second insulating layer INS2 may partially have an opening to include the third contact hole CH3 that exposes one area of the passivation layer PSV on the first pad electrode PDE1 in the pad area PDA.

During the process of forming the second insulating layer INS2, the first opening OPN1 of the passivation layer PSV is formed by removing one area of the passivation layer PSV that is exposed through the first contact hole CH1 of the second insulating layer INS2, the third opening OPN3 of the passivation layer PSV is formed by removing one area of the passivation layer PSV that is exposed through the second contact hole CH2 of the second insulating layer INS2, and the fifth opening OPN5 of the passivation layer PSV is formed by removing one area of the passivation layer PSV that is exposed through the third contact hole CH3 of the second insulating layer INS2.

During the process of forming the second insulating layer INS2, the passivation layer PSV may partially have openings to include the first opening OPN1, the third opening OPN3, and the fifth opening OPN5. One area of the first conductive pattern CP1 (or the upper electrode UE) may be exposed to the outside through the first opening OPN1 of the passivation layer PSV. One area of the second conductive pattern CP2 may be exposed to the outside through the third opening OPN3 of the passivation layer PSV. One area of the first pad electrode PDE1 may be exposed to the outside through the fifth opening OPN5 of the passivation layer PSV.

Furthermore, during the process of forming the second insulating layer INS2, one area of the passivation layer PSV that is positioned under the second layer SL and overlaps the second layer SL may remain, thus forming the first layer FL. The first layer FL may be positioned on the first pad electrode PDE1 in the pad area PDA. The first layer FL may include the same material as the passivation layer PSV, and may be provided in the same layer as the passivation layer PSV.

In the pad area PDA, the first layer FL, the second layer SL, and the third layer TL that are successively stacked from one surface of the first pad electrode PDE1 in the third direction DR3 may form the dummy pattern DMP. The dummy patterns DMP may partially overlap the first pad electrode PDE1 and reduce or minimize arcing defects, which occur on the first pad electrode PDE1 that is largely (extensively) exposed to the outside during the process of forming the third contact hole CH3 in the second insulating layer INS2.

In one or more embodiments, a dummy pattern is disposed in a pad area, thus reducing or minimizing crack defects, which occur during an outer lead bonding (OLB) process of bonding a pad electrode and a conductive adhesive component (or an anisotropic conductive film), thereby improving the reliability of the display device.

In one or more embodiments, a dummy pattern is disposed to overlap one area of the pad electrode, thus reducing a surface area with which the pad electrode is exposed to the outside, thereby reducing or minimizing arc defects, which occur due to charges concentrated on the exposed portion of the pad electrode. As a result, the reliability of the display device may be further improved.

In one or more embodiments, a method of fabricating the display device may be provided.

The effects, aspects, and features of the present disclosure are not limited by the foregoing, and other various effects, aspects, and features are anticipated herein.

While various one or more embodiments have been described above, those skilled in the art will appreciate that various modifications, additions and substitutions are possible, without departing from the scope of the present disclosure.

Therefore, the embodiments disclosed in this specification are only for illustrative purposes rather than limiting the technical scope of the present disclosure. The scope of the present disclosure must be defined by the accompanying claims.

What is claimed is:

1. A display device, comprising:
a substrate including a display area and a non-display area, the non-display area including a pad area;
a transistor and a conductive pattern on the substrate in the display area;
a via layer on the transistor and the conductive pattern to cover the transistor and the conductive pattern;
a first alignment electrode and a second alignment electrode on the via layer and spaced from each other;
a light emitting element between the first alignment electrode and the second alignment electrode;
a first electrode and a second electrode that are spaced from each other, and electrically connected to the light emitting element;
a plurality of pads on the substrate in the pad area; and
a dummy pattern on the substrate in the pad area, and spaced from the plurality of pads,
wherein the via layer and the dummy pattern comprise a same material.

2. The display device according to claim 1, wherein the via layer and the dummy pattern are in a same layer.

3. The display device according to claim 2, wherein the dummy pattern is adjacent to an edge of each of the plurality of pads.

4. The display device according to claim 3, wherein the dummy pattern is between two adjacent pads of the plurality of pads.

5. The display device according to claim 2, further comprising:
a passivation layer located between the substrate and the via layer in the display area, and located between the substrate and the dummy pattern in the pad area;
a first insulating layer on the via layer in the display area; and
a second insulating layer located on the first insulating layer in the display area, and located on the dummy pattern and the passivation layer in the pad area.

6. The display device according to claim 5, wherein a height of each of the plurality of pads in a thickness direction of the substrate is different from a height of the dummy pattern.

7. The display device according to claim 6, wherein the height of each of the plurality of pads is greater than the height of the dummy pattern.

8. The display device according to claim 5, wherein each of the plurality of pads comprises:
a first pad electrode on the substrate; and
a second pad electrode on the first pad electrode and electrically connected the first pad electrode,
wherein the first pad electrode is in a same layer as the conductive pattern, and
wherein the second pad electrode is in a same layer as at least one of the first electrode or the second electrode.

9. The display device according to claim 8,
wherein the conductive pattern comprises a first conductive pattern, a second conductive pattern, and a third conductive pattern that are spaced from each other between the substrate and the passivation layer,
wherein the first conductive pattern comprises an electrode of a storage capacitor electrically connected to the transistor,
wherein the second conductive pattern comprises a second power line to which a voltage of a second driving power supply is to be applied, and
wherein the third conductive pattern comprises a first power line to which a voltage of a first driving power supply different from the second driving power supply is to be applied.

10. The display device according to claim 9,
wherein the passivation layer includes a first opening exposing one area of the first conductive pattern, a second opening exposing a first area of the second conductive pattern, a third opening exposing a second area of the second conductive pattern, a fourth opening exposing one area of the third conductive pattern, and a fifth opening exposing a portion of the first pad electrode,
wherein the via layer includes a first contactor exposing the one area of the first conductive pattern, a second contactor exposing the first area of the second conductive pattern, a third contactor exposing the second area of the second conductive pattern, and a fourth contactor exposing the one area of the third conductive pattern, and
wherein the second insulating layer includes a first contact hole exposing the one area of the first conductive pattern, a second contact hole exposing the second area of the second conductive pattern, and a third contact hole exposing the portion of the first pad electrode.

11. The display device according to claim 10,
wherein the first alignment electrode contacts the one area of the third conductive pattern through the fourth contactor and the fourth opening, and is electrically connected to the third conductive pattern, and
wherein the second alignment electrode contacts the one area of the second conductive pattern through the second contactor and the second opening, and is electrically connected to the second conductive pattern.

12. The display device according to claim 11,
wherein the first electrode directly contacts the one area of the first conductive pattern through the first contact hole, the first contactor, and the first opening, and is electrically connected to the first conductive pattern, and
wherein the second electrode directly contacts the second area of the second conductive pattern through the second contact hole, the third contactor, and the third opening, and is electrically connected to the second conductive pattern.

13. The display device according to claim 12,
wherein the light emitting element comprises a first end electrically connected to the first electrode, and a second end electrically connected to the second electrode, and
wherein the light emitting element further comprises a p-type semiconductor layer on the first end, an n-type semiconductor layer on the second end, and an active layer between the p-type semiconductor layer and the n-type semiconductor layer.

14. The display device according to claim 1, further comprising:
a color conversion layer on the light emitting element and configured to change a wavelength of light emitted from the light emitting element; and
a color filter on the color conversion layer.

15. A display device, comprising:
a substrate including a display area and a non-display area, the non-display area including a pad area;
a transistor and a conductive pattern on the substrate in the display area;
a via layer on the transistor and the conductive pattern to cover the transistor and the conductive pattern;
a first alignment electrode and a second alignment electrode on the via layer and spaced from each other;
a light emitting element between the first alignment electrode and the second alignment electrode;
a first electrode and a second electrode that are spaced from each other, and electrically connected to the light emitting element;
a plurality of pads on the substrate in the pad area; and
a dummy pattern on the substrate in the pad area, and overlapping each of the plurality of pads,
wherein the dummy pattern comprises a first layer, a second layer, and a third layer that are successively stacked, and
wherein at least one of the first layer, the second layer, or the third layer comprises a same material as the via layer.

16. The display device according to claim 15, further comprising:
an interlayer insulating layer located between the substrate and the conductive pattern in the display area, and located between the substrate and the pads in the pad area;
a passivation layer on the interlayer insulating layer;
a first insulating layer on the via layer in the display area; and
a second insulating layer located on the first insulating layer in the display area, and located on the passivation layer in the pad area,
wherein the first layer is in a same layer as the passivation layer, the second layer is in a same layer as the via layer, and the third layer is in a same layer as the first insulating layer.

17. The display device according to claim 16, wherein the first layer comprises a same material as the passivation layer, the second layer comprises a same material as the via layer, and the third layer comprises a same material as the first insulating layer.

18. The display device according to claim 16, wherein each of the plurality of pads comprises:
a first pad electrode on the interlayer insulating layer; and
a second pad electrode on the first pad electrode and the dummy pattern and electrically connected the first pad electrode,
wherein the first pad electrode is in a same layer as the conductive pattern, and
wherein the second pad electrode is in a same layer as at least one of the first electrode or the second electrode.

19. A method of fabricating a display device, comprising:
forming a first conductive pattern, a second conductive pattern, a third conductive pattern, and a first pad electrode on a substrate including a display area and a non-display area, the non-display area including a pad area, and forming a passivation layer on the first to the third conductive patterns and the first pad electrode;
forming a via pattern including a contactor exposing one area of the passivation layer on the third conductive pattern, a first stepped portion corresponding to the second conductive pattern, and a second stepped portion corresponding to the first pad electrode, by depositing a via material layer on the passivation layer, disposing a mask on the via material layer, and performing a photolithography process;
exposing a portion of the third conductive pattern by removing one area of the passivation layer by a dry etching method;
forming, on the via pattern in the display area, a first alignment electrode and a second alignment electrode that are spaced from each other;
forming, on the via pattern and the first and the second alignment electrodes in the display area, a first insulating layer patterned to expose the first stepped portion;
forming a via layer to expose a portion of the passivation layer under the first stepped portion by removing the first stepped portion in the display area by an ashing method, and exposing, by removing the second stepped portion in the pad area by the ashing method, a portion of the passivation layer under the second stepped portion and forming a dummy pattern;
aligning light emitting elements between the first alignment electrode and the second alignment electrode in the display area;
forming a second insulating layer on the first insulating layer in the display area and the passivation layer in the non-display area; and
forming a first electrode and a second electrode electrically connected to the light emitting elements in the display area, and forming a second pad electrode electrically connected to the first pad electrode in the non-display area.

20. The method according to claim 19,
wherein the mask comprises a first portion, a second portion, a third portion, and a fourth portion,
wherein the first portion comprises a transparent portion allowing light to completely pass therethrough,
wherein the second portion comprises a blocking portion to completely block the light,
wherein the third portion comprises a semi-transparent portion allowing the light to partially pass therethrough,
wherein the fourth portion comprises a slit pattern portion having at least one slit pattern, and
wherein the first portion corresponds to the contactor of the via pattern, the third portion corresponds to the first stepped portion of the via pattern, the fourth portion corresponds to the second stepped portion of the via pattern, and the second portion corresponds to another area of the via pattern other than the contactor and the first and the second stepped portions.
